(19) United States
(12) Patent Application Publication
(10) Pub. No.: US 2026/0212816 A1
(43) Pub. Date: Jul. 23, 2026

(54) ELECTRONIC DEVICE

(71) Applicant: Samsung Display Co., Ltd., Yongin-si (KR)

(72) Inventors: Dhohun LEE, Yongin-si (KR); Kiyoung KIM, Yongin-si (KR); Seongjun LEE, Yongin-si (KR); Wonwoo CHOI, Yongin-si (KR); Minwoo HYEON, Yongin-si (KR)

(21) Appl. No.: 19/405,207

(22) Filed: Dec. 1, 2025

(30) Foreign Application Priority Data
Jan. 17, 2025 (KR) 10-2025-0007281

(51) Int. Cl. G09G 3/3233; H10K 59/121; H10K 59/131; H10K 59/65

(52) U.S. Cl. CPC G09G 3/3233; H10K 59/1213; H10K 59/131; H10K 59/65; G09G 2300/0426; G09G 2300/0819; G09G 2330/022

(57) ABSTRACT

An electronic device including: a display panel including a first display region having a first light transmittance, and a second display region having a second light transmittance lower than the first light transmittance, where the first display region includes a first region and a second region; a first electronic module under the display panel to correspond to the first region; and a second electronic module under the display panel to correspond to the second region, where the display panel includes a plurality of light emitting elements and a plurality of pixel circuits, each of the plurality of pixel circuits being electrically connected to a corresponding one of the plurality of light emitting elements, where a pixel circuit of the plurality of pixel circuits in the first region is configured to provide a first initializing voltage to the corresponding one of the plurality of light emitting elements.

### CROSS-REFERENCE TO RELATED APPLICATION

This application claims priority to and the benefit of Korean Patent Application No. 10-2025-0007281, filed on Jan. 17, 2025, in the Korean Intellectual Property Office, the entire disclosure of which is incorporated by reference herein.

### BACKGROUND

The present disclosure relates to an electronic device having improved display quality.

Various types of display devices have been used to provide image information. The display device may include an electronic module to receive an external signal, or to transmit an output signal to the outside. For example, the electronic module may include an infrared sensor, a proximity sensor, and/or a camera module, so a display device to obtain an image captured with higher quality is increasingly desirable.

An electronic module, such as a camera module, may be disposed in a region for displaying an image such that the region for displaying the image is increased in the display device. In the display panel, the number of pixels disposed in a region overlapped with the electronic module may be reduced to prevent the performance of the electronic module from being degraded.

### SUMMARY

Embodiments of the present disclosure provide an electronic device having improved display quality.

According to one or more embodiments of the present disclosure, an electronic device including: a display panel including a first display region having a first light transmittance, and a second display region having a second light transmittance lower than the first light transmittance, wherein the first display region includes a first region and a second region; a first electronic module under the display panel to correspond to the first region; and a second electronic module under the display panel to correspond to the second region, wherein the display panel includes a plurality of light emitting elements and a plurality of pixel circuits, each of the plurality of pixel circuits being electrically connected to a corresponding one of the plurality of light emitting elements, wherein a pixel circuit of the plurality of pixel circuits in the first region is configured to provide a first initializing voltage to the corresponding one of the plurality of light emitting elements, and a pixel circuit of the plurality of pixel circuits in the second region is configured to provide a second initializing voltage to the corresponding one of the plurality of light emitting elements, and wherein the first initializing voltage is different from the second initializing voltage, when the second electronic module is driven.

In one or more embodiments, the first initializing voltage has a voltage level higher than a voltage level of the second initializing voltage, when the second electronic module is driven.

In one or more embodiments, the first electronic module receives an external light, and wherein the second electronic module radiates a light toward the display panel.

In one or more embodiments, the first electronic module includes an infrared camera, and wherein the second electronic module includes a dot projector.

In one or more embodiments, the pixel circuit in the second display region is configured to provide a third initializing voltage, which is different from the first initializing voltage and the second initializing voltage, to the corresponding one of the plurality of light emitting elements.

In one or more embodiments, the third initializing voltage has a voltage level higher than a voltage level of the first initializing voltage, and the voltage level of the first initializing voltage is higher than a voltage level of the second initializing voltage, when the second electronic module is driven.

In one or more embodiments, the first initializing voltage has a voltage level greater than −3.4 V (volt) and less than 0 V.

In one or more embodiments, the second initializing voltage has a voltage level greater than −3.8 V (volt) and less than 0 V.

In one or more embodiments, the first initializing voltage has a voltage level equal to a voltage level of the second initializing voltage, when the second electronic module is not driven.

In one or more embodiments, one of the plurality of light emitting elements includes a first electrode and a second electrode, the second electrode being connected to a first power line configured to provide a first power.

In one or more embodiments, each of the first initializing voltage and the second initializing voltage has a voltage level lower than a voltage level of the first power, when the second electronic module is not driven.

In one or more embodiments, one of the plurality of pixel circuits includes: a first transistor connected between the first electrode and a second power line configured to provide second power having a voltage level higher than a voltage level of the first power; a second transistor connected to a data line configured to receive a scan signal; and a third transistor connected to the first electrode.

In one or more embodiments, the third transistor of the pixel circuit located in the first region is connected to a first initializing voltage line configured to provide the first initializing voltage.

In one or more embodiments, the third transistor of the pixel circuit located in the second region is connected to a second initializing voltage line configured to provide the second initializing voltage.

In one or more embodiments, an electronic device including: a display panel including a first region and a second region; a first electronic module overlapped with the first region, when viewed in a plan view; and a second electronic module overlapped with the second region, when viewed in the plan view, wherein the display panel includes a plurality of light emitting elements and a plurality of pixel circuits, each of the plurality of pixel circuits being electrically connected to a corresponding one of the plurality of light emitting elements, wherein a pixel circuit of the at least one pixel circuit overlapped with the first electronic module is connected to a first initializing voltage line configured to provide a first initializing voltage, and wherein a pixel circuit of the plurality of pixel circuits overlapped with the second electronic module is connected to a second initializing voltage line configured to provide a second initializing voltage different from the first initializing voltage.

In one or more embodiments, the first initializing voltage has a voltage level higher than a voltage level of the second initializing voltage.

In one or more embodiments, the first electronic module is configured to receive an external light, and wherein the second electronic module is configured to radiate a light toward the display panel.

In one or more embodiments, the first electronic module includes an infrared camera, and wherein the second electronic module includes a dot projector.

In one or more embodiments, the first initializing voltage has a voltage level greater than −3.4 V (volt) and less than 0 V, and wherein the second initializing voltage has a voltage level greater than −3.8 V and less than 0 V.

In one or more embodiments, one of the plurality of light emitting elements includes a first electrode and a second electrode, the second electrode connected to a first power line configured to provide a first power, and wherein each of the first initializing voltage and the second initializing voltage has a voltage level lower than a voltage level of the first power.

### BRIEF DESCRIPTION OF THE DRAWINGS

The above and other aspects and features of the present disclosure will become apparent by describing in detail embodiments thereof with reference to the accompanying drawings.

FIG. 1 is a block diagram illustrating an electronic device according to one or more embodiments of the present disclosure.

FIG. 2 is a perspective view of an electronic device according to one or more embodiments of the present disclosure.

FIG. 3 is an exploded perspective view of an electronic device according to one or more embodiments of the present disclosure.

FIG. 4 is a cross-sectional view of an electronic device taken along the line I-I′ illustrated in FIG. 3 according to one or more embodiments of the present disclosure.

FIG. 5 is a plan view of a display panel according to one or more embodiments of the present disclosure.

FIG. 6 is a cross-sectional view of a display panel taken along the line II-II′ of FIG. 5 according to one or more embodiments of the present disclosure.

FIG. 7 is a plan view of a first display region according to one or more embodiments of the present disclosure.

FIG. 8A is an equivalent circuit diagram of a first pixel according to one or more embodiments of the present disclosure.

FIG. 8B is a timing diagram to describe the operation of a plurality of pixels according to one or more embodiments of the present disclosure.

FIG. 9 is a plan view of a second display region according to one or more embodiments of the present disclosure.

FIG. 10A is an equivalent circuit diagram of a second pixel according to one or more embodiments of the present disclosure.

FIG. 10B is an equivalent circuit diagram of a second pixel according to one or more embodiments of the present disclosure.

FIG. 11 is an equivalent circuit diagram of a third pixel according to one or more embodiments of the present disclosure.

FIG. 12 illustrates the operation of an electronic device according to one or more embodiments of the present disclosure.

FIG. 13A illustrates graphs of a luminance as a function of a voltage difference according to one or more embodiments of the present disclosure.

FIG. 13B illustrates graphs of a luminance as a function of a voltage difference according to one or more embodiments of the present disclosure.

FIG. 14 is a plan view illustrating a display panel according to one or more embodiments of the present disclosure.

FIG. 15 is a cross-sectional view illustrating a display panel according to one or more embodiments of the present disclosure.

FIG. 16 is a block diagram of an electronic device according to one or more embodiments of the present disclosure.

FIG. 17 is a schematic view illustrating an electronic device according to various embodiments.

### DETAILED DESCRIPTION

In the specification, the expression that a first component (or region, layer, or part) is “on”, “connected to”, or “coupled to” a second component refers to that the first component is directly on, connected to, or coupled to the second component or refers to that a third component is interposed therebetween.

The same reference numeral will be assigned to the same component. In addition, in drawings, thicknesses, proportions, and dimensions of components may be exaggerated to describe the technical features effectively. The term “and/or” includes any and all combinations of one or more of associated components

Although the terms “first”, or “second” may be used to describe various components, the components should not be construed as being limited by the terms. The terms are only used to distinguish one component from another component. For example, without departing from the scope and spirit of the present disclosure, a first component may be referred to as a second component, and similarly, the second component may be referred to as the first component. The singular forms are intended to include the plural forms unless the context clearly indicates otherwise.

In addition, the terms “under”, “at a lower portion”, “above”, “an upper portion” are used to describe the relationship between components illustrated in drawings. The terms are relative and will be described with reference to a direction indicated in the drawing.

It will be further understood that the terms “comprise,” “include,” or “including,” or “have” or “having” specify the presence of stated features, numbers, steps, operations, components, parts, or the combination thereof, but do not preclude the presence or addition of one or more other features, numbers, steps, operations, components, components, and/or the combination thereof.

The terms “part” and “unit” refer to a software component or a hardware component to perform a specific function. The hardware component may include field-programmable gate array (FPGA) or an application-specific integrated circuit (ASIC). The software component may refer to an executable code and/or data used by the executable code in an addressable storage medium. Accordingly, software components may be, for example, object-oriented software components, class components, and task components, and may include processes, functions, properties, procedures, subroutines, program code segments, driver data, firmware, micro-codes, circuits, data, database, data structures, tables, arrangements or variables.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless defined otherwise, all terms (including technical terms and scientific terms) used in the specification have the same meaning as commonly understood by one skilled in the art to which the present disclosure belongs. Furthermore, terms such as terms defined in the dictionaries commonly used should be interpreted as having a meaning consistent with the meaning in the context of the related technology, and should not be interpreted in ideal or overly formal meanings unless explicitly defined herein.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Hereinafter, embodiments of the present disclosure will be described with reference to drawings.

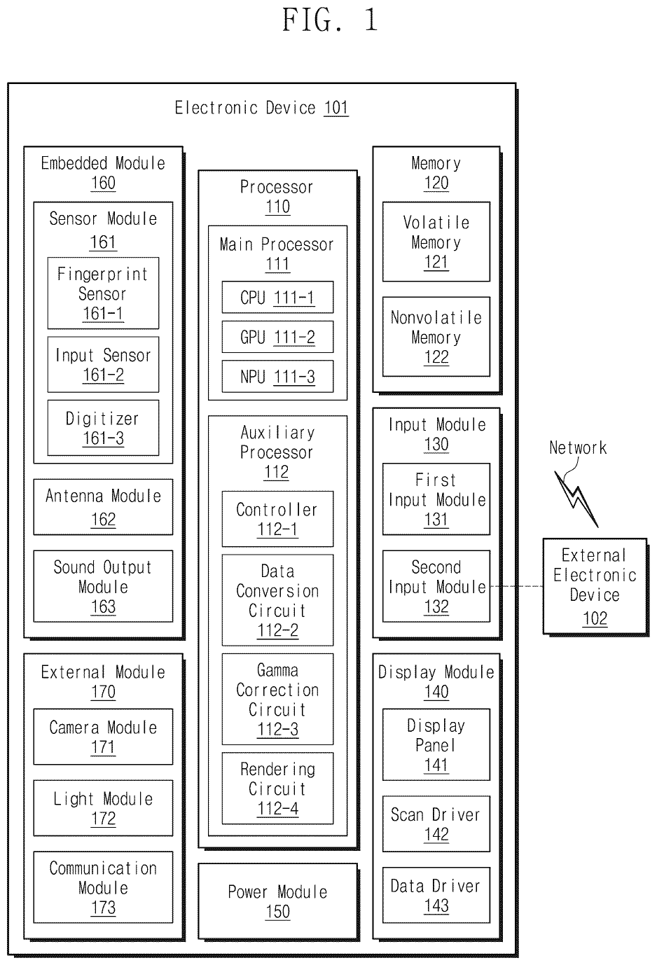

FIG. 1 is a block diagram illustrating an electronic device according to one or more embodiments of the present disclosure.

Referring to FIG. 1, an electronic device 101 outputs a variety of information through a display module 140 in an operating system. When a processor 110 executes an application stored in a memory 120, the display module 140 provides a user with application information through a display panel 141.

The processor 110 obtains an external input through an input module 130 or a sensor module 161 and executes an application corresponding to the external input. For example, when the user selects a camera icon displayed on the display panel 141, the processor 110 obtains a user input through an input sensor 161-2 and activates a camera module 171. The processor 110 transfers image data corresponding to a photographed image obtained through the camera module 171 to the display module 140. The display module 140 may display an image corresponding to the photographed image through the display panel 141.

As another example, when authentication for personal information is performed in the display module 140, a fingerprint sensor 161-1 obtains input fingerprint information as input data. The processor 110 compares the input data obtained through the fingerprint sensor 161-1 with authentication data stored in the memory 120 and executes an application depending on a comparison result. The display module 140 may display information executed depending on logic of the application, through the display panel 141.

As another example, when the user selects a music streaming icon displayed on the display module 140, the processor 110 obtains the user input through the input sensor 161-2 and activates a music streaming application stored in the memory 120. When a music play command is input to the music streaming application, the processor 110 activates a sound output module 163 and provides the user with sound information corresponding to the music play command.

The operation of the electronic device 101 has been briefly described above. Below, a configuration of the electronic device 101 will be described in detail. Some of components of the electronic device 101 to be described later may be implemented integrally into one component, and the one component may be divided into two or more components.

The electronic device 101 may communicate with an external electronic device 102 over a network (e.g., a short-range wireless communication network or a long-range wireless communication network). According to one or more embodiments, the electronic device 101 may include the processor 110, the memory 120, the input module 130, the display module 140, a power module 150, an embedded module 160, and an external module 170. According to one or more embodiments, the electronic device 101 may not include at least one of the above components or may further include at least one different component. According to one or more embodiments, some of the above components (e.g., the sensor module 161, an antenna module 162, or the sound output module 163) may be integrated into any other component (e.g., the display module 140).

The processor 110 may execute software to control at least one component (e.g., a hardware or software component) of the electronic device 101 connected to the processor 110 and may perform various data processing or operations. According to one or more embodiments, as at least a part of the data processing or operations, the processor 110 may store a command or data received from any other component (e.g., the input module 130, the sensor module 161, or a communication module 173) in a volatile memory 121, may process the command or data stored in the volatile memory 121, and may store the processed data in a nonvolatile memory 122.

The processor 110 may include a main processor 111 and an auxiliary processor 112. The main processor 111 may include at least one of a central processing unit (CPU) 111-1 or an application processor (AP). The main processor 111 may further include at least any one of a graphic processing unit (GPU) 111-2, a communication processor (CP), and an image signal processor (ISP). The main processor 111 may further include a neural processing unit (NPU) 111-3. The neural processing unit 111-3 may be a processor specialized for processing of an artificial intelligence model, and the artificial intelligence model may be created through machine learning. The artificial intelligence model may include a plurality of artificial neural network layers. The artificial neural network may include one of a deep neural network (DNN), a convolutional neural network (CNN), a recurrent neural network (RNN), a restricted boltzmann machine (RBM), a deep belief network (DBN), a bidirectional recurrent deep neural network (BRDNN), a deep Q-network, or a combination of at least two thereof, but the present disclosure is not limited thereto. Additionally or alternatively, the artificial intelligence model may include a software structure in addition to a hardware structure. At least two of the above processing units and processors may be implemented integrally into one component (e.g., a single chip), or each of the above processing units and processors may be implemented in the form of an independent component (e.g., a plurality of chips).

The auxiliary processor 112 may include a controller 112-1. The controller 112-1 may include an interface conversion circuit and/or a timing control circuit. The controller 112-1 receives an image signal from the main processor 111 and outputs image data obtained by converting a data format of the image signal so as to be suitable for the specification of an interface with the display module 140. The controller 112-1 may output various kinds of control signals necessary to drive the display module 140.

The auxiliary processor 112 may further include a data conversion circuit 112-2, a gamma correction circuit 112-3, and a rendering circuit 112-4. The data conversion circuit 112-2 may receive image data from the controller 112-1, and may compensate for the image data such that an image is displayed with a desired luminance depending on a characteristic of the electronic device 101 or user settings or may convert the image data to reduce power consumption or to compensate for an afterimage. The gamma correction circuit 112-3 may convert the image data or a gamma reference voltage such that an image displayed on the electronic device 101 has a desired gamma characteristic. The rendering circuit 112-4 may receive the image data from the controller 112-1 and may render the image data in consideration of a pixel arrangement of the display panel 141 applied to the electronic device 101. At least one of the data conversion circuit 112-2, the gamma correction circuit 112-3, and the rendering circuit 112-4 may be integrated into any other component (e.g., the main processor 111 or the controller 112-1). At least one of the data conversion circuit 112-2, the gamma correction circuit 112-3, and the rendering circuit 112-4 may be integrated into a data driver 143 to be described later.

The memory 120 may store various data used by at least one component (e.g., the processor 110 or the sensor module 161) of the electronic device 101 and input data or output data for a command related thereto. The memory 120 may include at least one of the volatile memory 121 and the nonvolatile memory 122.

The input module 130 may receive a command or data to be used by a component (e.g., the processor 110, the sensor module 161, or the sound output module 163) of the electronic device 101 from the outside of the electronic device 101 (e.g., the user or the external electronic device 102).

The input module 130 may include a first input module 131 to receive a command or data from the user and a second input module 132 to receive a command or data from the external electronic device 102. The first input module 131 may include a microphone, a mouse, a keyboard, a key (e.g., a button), or a pen (e.g., a passive pen or an active pen). The second input module 132 may support a specified protocol capable of connecting to the external electronic device 102 by wire or wirelessly. According to one or more embodiments, the second input module 132 may include a high definition multimedia interface (HDMI), a universal serial bus (USB) interface, a secure digital (SD) card interface, and/or an audio interface. The second input module 132 may include a connector, such as an HDMI connector, a USB connector, an SD card connector, or an audio connector (e.g., a headphone connector), which is capable of being physically connected to the external electronic device 102.

The display module 140 visually provides information to the user. The display module 140 may include the display panel 141, a scan driver 142, and the data driver 143. The display module 140 may further include a window, a chassis, and a bracket to protect the display panel 141.

The display panel 141 may include a liquid crystal display panel, an organic light emitting display panel, or an inorganic light emitting display panel, and the type of the display panel 141 is not particularly limited. The display panel 141 may be of a rigid type or may be of a flexible type capable of being rolled and/or folded. The display module 140 may further include a supporter supporting the display panel 141, a bracket, or a heat radiation member.

The scan driver 142 serving as a driving chip may be mounted in the display panel 141. In addition, the scan driver 142 may be integrated into the display panel 141. For example, the scan driver 142 may include an amorphous silicon (ASG) TFT gate driver circuit, a low temperature polycrystalline silicon (LTPS) TFT gate driver circuit, and/or an oxide semiconductor (OSG) TFT gate driver circuit provided in the display panel 141. The scan driver 142 receives a control signal from the controller 112-1, and output scan signals to the display panel 141 in response to the control signal.

The display panel 141 may further include a light emitting driver. The light emitting driver outputs a light emitting control signal to the display panel 141, in response to the control signal received from the controller 112-1. The light emitting driver may be formed separately from the scan driver 142 or may be integrated into the scan driver 142.

The data driver 143 receives a data control signal from the controller 112-1. After converting image data into an analog voltage (e.g., a data voltage) in response to the control signal, the data driver 143 outputs data voltages to the display panel 141. The data driver 143 may be integrated into a different component (e.g., the controller 112-1). The functions of the interface conversion circuit and the timing control circuit of the controller 112-1 described above may be integrated into the data driver 143.

The display module 140 may further include a light emitting driver, and/or a voltage generation circuit. The voltage generation circuit may output various types of voltages necessary to drive the display panel 141.

The power module 150 supplies a power to the components of the electronic device 101. The power module 150 may include a battery which charges a power supply voltage. The battery may include a primary cell not rechargeable, a secondary cell rechargeable, and/or a fuel cell. The power module 150 may include a power management integrated circuit (PMIC). The PMIC supplies power optimized for each of the modules described above and modules to be described later. The power module 150 may include a wireless power transmission/reception member electrically connected to the battery. The wireless power transmission/reception member may include a plurality of antenna radiators that are in the form of a coil.

The electronic device 101 may further include the embedded module 160 and the external module 170. The embedded module 160 may include the sensor module 161, the antenna module 162, and the sound output module 163. The external module 170 may include the camera module 171, a light module 172, and the communication module 173.

The sensor module 161 may sense an input by a user body and/or an input by a pen in the first input module 131 and may generate an electrical signal and/or a data value corresponding to the input. The sensor module 161 may include at least one of the fingerprint sensor 161-1, the input sensor 161-2, or a digitizer 161-3.

The fingerprint sensor 161-1 may generate a data value corresponding to the user fingerprint. The fingerprint sensor 161-1 may include one of an optical fingerprint sensor or a capacitive fingerprint sensor.

The input sensor 161-2 may generate a data value corresponding to coordinate information of the input by the user body or the input by the pen. The input sensor 161-2 generates a change in capacitance, which is made due to the input, in the form of a data value. The input sensor 161-2 may sense the input by the passive pen or may exchange data with the active pen.

The input sensor 161-2 may measure a biometric signal, such as blood pressure, moisture, and/or body fat. For example, when the user touches a user body part to a sensor layer or a sensing panel without moving for a specific period of time, the input sensor 161-2 may sense the biometric signal based on a change in an electric field caused by the body part and may output the information desired by the user to the display module 140.

The digitizer 161-3 may generate a data value corresponding to the coordinate information of the input by the pen. The digitizer 161-3 generates an electromagnetic change, which is made by the input, in the form of a data value. The digitizer 161-3 may sense the input by the passive pen or may exchange data with the active pen.

At least one of the fingerprint sensor 161-1, the input sensor 161-2, and the digitizer 161-3 may be implemented in the form of a sensor layer, which is formed on the display panel 141, through subsequent processes. The fingerprint sensor 161-1, the input sensor 161-2, and the digitizer 161-3 may be disposed above/on the display panel 141, and any one (e.g., the digitizer 161-3) of the fingerprint sensor 161-1, the input sensor 161-2, and the digitizer 161-3 may be disposed below/under the display panel 141.

At least two of the fingerprint sensor 161-1, the input sensor 161-2, and the digitizer 161-3 may be integrally formed in the form of one sensing panel through the same process. When the at least two of the fingerprint sensor 161-1, the input sensor 161-2, and the digitizer 161-3 may be integrally formed in the form of one sensing panel, the sensing panel may be disposed between the display panel 141 and the window disposed above/on the display panel 141. According to one or more embodiments, the sensing panel may be disposed on the window, and the position of the sensing panel is not specifically limited.

At least one of the fingerprint sensor 161-1, the input sensor 161-2, or the digitizer 161-3 may be embedded in the display panel 141. In other words, at least one of the fingerprint sensor 161-1, the input sensor 161-2, or the digitizer 161-3 may be concurrently (e.g., simultaneously) formed through a process for forming components (e.g., a light emitting diode and a transistor) included in the display panel 141.

In addition, the sensor module 161 may generate an electrical signal or a data value corresponding to an internal state or an external state of the electronic device 101. The sensor module 161 may further include, for example, a gesture sensor, a gyro sensor, a pressure sensor, a magnetic sensor, an acceleration sensor, a grip sensor, a proximity sensor, a color sensor, an infrared (IR) sensor, a biometric sensor, a temperature sensor, a humidity sensor, and/or an illuminance sensor.

The antenna module 162 may include at least one antenna to transmit and/or receive the signal or power to and/or from an external source. According to one or more embodiments, through an antenna suitable for a communication scheme, the communication module 173 may transmit a signal to an external electronic device 102 or may receive a signal from the external electronic device 102. An antenna pattern of the antenna module 162 may be integrated into one component (e.g., the display panel 141) of the display module 140 and/or the input sensor 161-2.

The sound output module 163 that is a device for outputting a sound signal to the outside of the electronic device 101 may include, for example, a speaker used for general purposes such as multimedia playback and/or recording playback and a receiver used exclusively for receiving calls. According to one or more embodiments, the receiver and the speaker may be either integrally or separately implemented. A sound output pattern of the sound output module 163 may be integrated into the display module 140.

The camera module 171 may photograph a still image and/or a moving image. According to one or more embodiments, the camera module 171 may include at least one lens, an image sensor, or an image signal processor. The camera module 171 may further include an infrared camera capable of measuring the presence or absence of the user, the position of the user, and/or the line of sight of the user.

The light module 172 may provide a light. The light module 172 may include a light emitting diode or a xenon lamp. The light module 172 may operate in conjunction with the camera module 171 or may operate independently.

The communication module 173 may establish a wired or wireless communication channel between the electronic device 101 and the external electronic device 102 and may support communication execution through the established communication channel. The communication module 173 may include one of a wireless communication module, such as a cellular communication module, a short-range wireless communication module, or a global navigation satellite system (GNSS) communication module, and a wired communication module, such as a local area network (LAN) communication module or a power line communication module or may include all thereof. The communication module 173 may communicate with the external electronic device 102 over a short-range communication network such as Bluetooth, Wi-Fi direct, or infrared data association (IrDA) or a long-range communication network such as a cellular network, an Internet, or a computer network (e.g., a LAN or WAN). Various types of communication modules described above may be implemented into one chip or implemented in the form of separate chips.

The input module 130, the sensor module 161, and the camera module 171 may be used to control the operation of the display module 140 while operating with the processor 110.

The processor 110 outputs commands or data to the display module 140, the sound output module 163, the camera module 171, and/or the light module 172 based on the input data received from the input module 130. For example, the processor 110 may generate the image data corresponding to the input data applied through the mouse or the active pen and may output the image data to the display module 140; alternatively, the processor 110 may generate command data corresponding to the input data and may output the command data to the camera module 171 or the light module 172. When input data are not received from the input module 130 during a specific period of time, the processor 110 may switch an operating mode of the electronic device 101 to a low-power mode or a sleep mode such that the power consumption of the electronic device 101 is reduced.

The processor 110 outputs commands or data to the display module 140, the sound output module 163, the camera module 171, and/or the light module 172 based on the sensing data received from the sensor module 161. For example, the processor 110 may compare authentication data, which is obtained through the fingerprint sensor 161-1, with authentication data stored in the memory 120 and may then execute an application depending on a comparison result. The processor 110 may execute a command based on the sensing data sensed by the input sensor 161-2 or the digitizer 161-3 or may output image data corresponding to the sensing data to the display module 140. When the sensor module 161 includes a temperature sensor, the processor 110 may receive temperature data about the measured temperature from the sensor module 161 and may further correct luminance of the image data based on the temperature data.

The processor 110 may receive measurement data about the presence or absence of the user, the position of the user, and/or the line of sight of the user from the camera module 171. The processor 110 may further correct the luminance of the image data based on the measurement data. For example, the processor 110 that determines the presence or absence of the user through the input from the camera module 171 may output, to the display module 140, image data having luminance corrected through the data conversion circuit 112-2 and/or the gamma correction circuit 112-3.

Some of the above components may be connected to each other through a communication scheme between peripheral devices, for example, a bus, a general purpose input/output (GPIO), a serial peripheral interface (SPI), a mobile industry processor interface (MIPI), and/or a ultra-path interconnect (UPI) link and may exchange signals (e.g., commands or data). The processor 110 may communicate with the display module 140 through a specific interface. For example, one of the communication schemes described above may be used, and the present disclosure is not limited thereto.

The electronic device 101 according to various embodiments of the present disclosure may be implemented as various types of devices. The electronic device 101 may include, for example, at least one of a portable communication device (e.g., a smartphone), a computer device, a portable multimedia device, a portable medical device, a camera, a wearable device, and home appliances. The electronic device 101 according to one or more embodiments of the present disclosure is not limited to the above devices.

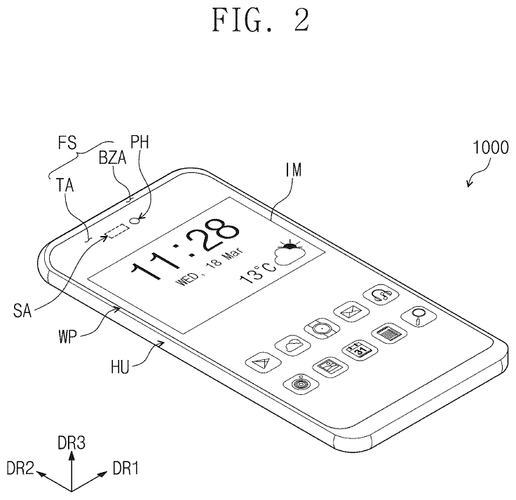

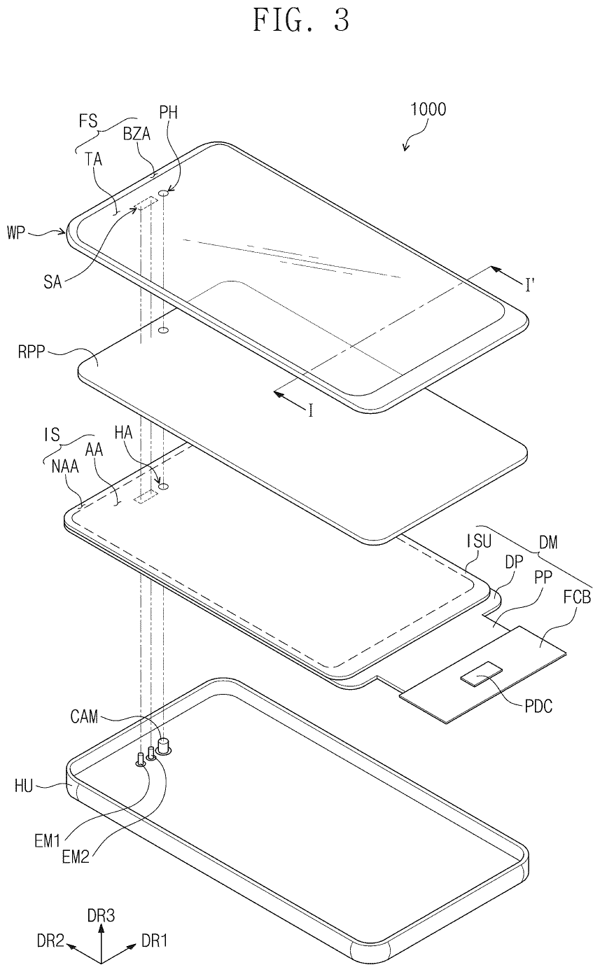

FIG. 2 is a perspective view of an electronic device according to one or more embodiments of the present disclosure, and FIG. 3 is an exploded perspective view of an electronic device according to one or more embodiments of the present disclosure.

Referring to FIGS. 2 and 3, an electronic device 1000 may be a device which is activated in response to an electrical signal. The electronic device 1000 may include various embodiments. For example, the electronic device 1000 may be used for small and medium-size electronic devices, such as a television, a laptop computer, a personal digital terminal, a vehicle navigation unit, a game camera, a portable electronic device, and/or a camera. In addition, the above examples are suggested only as an embodiment, and it is obvious to those skilled in the art that the electronic device 1000 may be applied to any other electronic device(s) without departing from the technical spirit and scope of the present disclosure. According to one or more embodiments, the electronic device 1000 is provided in the form of a smartphone by way of example.

The electronic device 1000 may display an image IM on a display surface FS, which is parallel to each of a first direction DR1 and a second direction DR2, in a third direction DR3. The image IM may include a still image as well as a video (or a moving picture). A clock and icons are illustrated in FIG. 2 as an example of the image IM. The display surface FS for displaying the image IM may correspond to a front surface of the electronic device 1000 and may correspond to a front surface of a window panel WP.

According to one or more embodiments, a front surface (or a top surface) and a rear surface (or a bottom surface) of each of members are defined based on a direction in which the image IM is displayed. The front surface and the rear surface may face each other in the third direction DR3, and a normal direction to each of the front surface and the rear surface may be parallel to the third direction DR3. Meanwhile, the first direction DR1, the second direction DR2, and the third direction DR3 may be relative concepts and may be changed to different directions.

According to one or more embodiments of the present disclosure, the electronic device 1000 may sense an external input of the user, which is applied from the outside. The user input may include various types of external inputs, such as inputs made by a part of a physical body of the user, light, heat, and/or pressure. In addition, the electronic device 1000 may sense the input of the user, which is applied to the side surface or rear surface of the electronic device 1000 depending on a structure of the electronic device 1000, and the present disclosure is not limited to one embodiment.

The electronic device 1000 may include the window panel WP, an anti-reflector RPP, a display module DM, a camera module CAM, a first electronic module EM1, a second electronic module EM2, and a housing HU. According to one or more embodiments, the window panel WP is coupled to the housing HU to form an outer appearance of the electronic device 1000.

The window panel WP may include an optically transparent insulating material. For example, the window panel WP may include glass and/or plastic. The window panel WP may have a multi-layer structure or a single-layer structure. For example, the window panel WP may include a plurality of plastic films bonded to each other by an adhesive or may have a glass substrate and a plastic film bonded to each other by an adhesive.

The display surface FS of the window panel WP defines the front surface of the display device DD as described above. The display surface FS may include a transmissive region TA and a bezel region BZA.

The transmissive region TA may be an optically transparent region. For example, the transmissive region TA may be a region having at least about 90% of visible ray transmittance. The transmissive region TA may include a first sensing region PH and a second sensing region SA defined in the transmissive region TA.

The camera module CAM may be disposed in a region overlapped with the first sensing region PH.

The first electronic module EM1 and the second electronic module EM2 may be disposed in a region overlapped with the second sensing region SA.

The bezel region BZA may have a light transmittance lower than a light transmittance of the transmissive region TA. The bezel region BZA may have a specific color. The bezel region BZA defines a shape of the transmissive region TA. The bezel region BZA may be adjacent to the transmissive region TA while being around (e.g., surrounding) the transmissive region TA along an edge or a periphery of the transmissive region TA. According to one or more embodiments of the present disclosure, the bezel region BZA may be omitted from the window panel WP.

The anti-reflector RPP may be disposed under the window panel WP. The anti-reflector RPP decreases the reflectance of an external light incident from above the window panel WP. According to one or more embodiments of the present disclosure, the anti-reflector RPP may be omitted or may be embedded in the display module DM.

The display module DM may display the image IM and may sense an external input. The display module DM includes a front surface IS including an active region AA and a peripheral region NAA. The active region AA may be activated in response to an electrical signal.

According to one or more embodiments, the active region AA may be a region for displaying the image IM while sensing the external input. The transmissive region TA is overlapped with at least the active region AA. For example, the transmissive region TA is overlapped with the front surface of the active region AA or with at least a portion of the active region AA. Accordingly, the user may view the image IM through the transmissive region TA or provide the external input through the transmissive region TA. However, this is provided only for the illustrative purpose. For example, in the active region AA, a region for displaying the image IM may be separated from a region for sensing the external input. However, the present disclosure is not limited to any one embodiment.

A sensing hole HA may be defined in the active region AA. The sensing hole HA may be disposed to correspond to the first sensing region PH. The camera module CAM may receive a signal from the outside, through the sensing hole HA.

A partial region of the active region AA may correspond to the second sensing region SA. Accordingly, the electronic device 1000 may display the image IM through the second sensing region SA.

The peripheral region NAA may be covered by the bezel region BZA. The peripheral region NAA is adjacent to the active region AA. The peripheral region NAA may be around (e.g., may surround) the active region AA along an edge or a periphery of the active region AA. The peripheral region NAA may include a driving circuit or a driving wiring disposed to drive the active region AA.

According to one or more embodiments, the display module DM is assembled with the window panel WP in a flat state in which the active region AA and the peripheral region NAA face the window panel WP. However, this is provided only for the illustrative purpose. For example, a portion of the peripheral region NAA of the display module DM may be curved. In this case, the peripheral region NAA may partially face the rear surface of the display device DD to reduce the size of the bezel region BZA on the front surface of the display device DD. In addition, the display module DM may be assembled in the state that even the active region AA is partially curved.

The display module DM may include a display panel DP, an input sensor ISU, and a driving circuit DC (e.g., a panel driving circuit PDC).

The display panel DP may be a component to substantially generate the image IM. The image IM generated by the display panel DP may be viewed from the outside through the transmissive region TA.

The input sensor ISU senses an external input applied from the outside. As described above, the input sensor ISU may sense an external input provided on the window panel WP.

The display panel DP may include a pad region PP. A plurality of signal pads may be disposed in the pad region PP of the display panel DP. The display panel DP may be electrically connected to a printed circuit board FCB through signal pads. According to one or more embodiments, a driving chip may be mounted in the pad region PP, to generate signals necessary for the operation of the display panel DP.

The printed circuit board FCB may include various kinds of driving circuits to drive the display panel DP and the input sensor ISU, and a connector to supply power. According to one or more embodiments, the printed circuit board FCB may include a panel driving circuit PDC to drive the display panel DP. The panel driving circuit PDC may be formed in the form of an integrated circuit (IC) or may be mounted on the printed circuit board FCB.

The camera module CAM, the first electronic module EM1, and the second electronic module EM2 may be disposed under the display panel DP.

The housing HU is coupled to the window panel WP. As the housing HU is coupled to the window panel WP, the housing HU may provide a space for receiving the anti-reflector RPP, the display module DM, the camera module CAM, the first electronic module EM1, and the second electronic module EM2.

The housing HU may include a material having higher rigidity. For example, the housing HU may include a plurality of frames and/or plates including glass, plastic, and/or metal, or the combination thereof. The housing HU may stably protect components, which are received in an inner space of the housing HU, of the display device DD from an external impact.

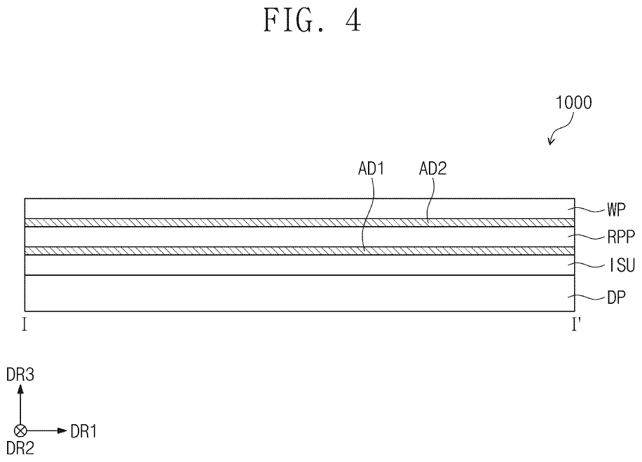

FIG. 4 is a cross-sectional view of an electronic device taken along the line I-I′ illustrated in FIG. 3 according to one or more embodiments of the present disclosure.

FIG. 4 illustrates a cross-section illustrating a portion of the electronic device 1000 and defined by the first direction DR1 and the third direction DR3. As illustrated in FIG. 4, components of the electronic device 1000 are simply illustrated, for the convenience of the explanation about the stack relation between the components.

Referring to FIG. 4, the electronic device 1000 may include the display panel DP, the input sensor ISU, the anti-reflector RPP, and the window panel WP. At least some of the display panel DP, the input sensor ISU, the anti-reflector RPP, and the window panel WP may be formed through subsequent processes or may be coupled to each other through an adhesive member. For example, the input sensor ISU and the anti-reflector RPP may be coupled to each other by an adhesive member AD1. The anti-reflector RPP and the window panel WP may be coupled to each other by an adhesive member AD2.

The adhesive members AD1 and AD2 may be transparent adhesive members, such as a pressure sensitive adhesive (PSA) film, an optically clear adhesive (OCA) film, or optically clear resin (OCR). The adhesive member to be described below may include a typical adhesive or a typical adhesion agent. According to one or more embodiments of the present disclosure, the anti-reflector RPP and the window panel WP may be substituted with different components or omitted.

The input sensor ISU, which is formed through a subsequent process to the display panel DP, among the input sensor ISU, the anti-reflector RPP, and the window panel WP is directly disposed on the display panel DP. In this specification, “component B directly disposed on component A” refers to the absence of an additional adhesive layer/adhesive member interposed between component A and component B. Component B is formed on a base surface having component A through a subsequent process after component A is formed.

According to one or more embodiments, the anti-reflector RPP and the window panel WP are in a “panel” type, and the input sensor ISU is in a “layer” type. The “panel” type may include a base layer providing a base surface, for example, a synthetic resin film, a composite material film, and/or a glass substrate, but the “layer” type may not include the base layer. In other words, components in the “layer” type are disposed on a base surface having any other component. According to one or more embodiments of the present disclosure, the anti-reflector RPP and the window panel WP may be in the “layer” type.

The display panel DP generates an image, and the input sensor ISU obtains coordinate information of the external input (e.g., a touch event). In one or more embodiments, the display device DD according to one or more embodiments of the present disclosure may further include a protection member disposed on the bottom surface (or rear surface) of the display panel DP. The protection member and the display panel DP may be coupled to each other through an adhesive member.

The display panel DP according to one or more embodiments of the present disclosure may be an emissive-type display panel, but the present disclosure is not particularly limited thereto. For example, the display panel DP may be an organic light emitting display panel, a quantum dot light emitting display panel, a micro-LED display panel, and/or a nano-LED display panel. The panels are classified depending on a material forming a light emitting element. A light emitting layer of the organic light emitting display panel may include an organic light emitting material. A light emitting layer of the quantum dot light emitting display panel may include a quantum dot and a quantum rod. A light emitting layer of the micro-LED display panel may include a micro-LED. A light emitting layer of the nano-LED display panel may include a nano-LED.

The anti-reflector RPP decreases the reflectance of an external light incident from above the window panel WP. The anti-reflector RPP according to one or more embodiments of the present disclosure may include a phase retarder and a polarizer. The phase retarder may be in a film type or a liquid crystal coating type. The polarizer may be in a film type or a liquid crystal coating type. The film-type polarizer may include a stretched synthetic resin film, and the liquid crystal coating type polarizer may include liquid crystals aligned in a specific array. The phase retarder and the polarizer may further include a protection film. The phase retarder and the polarizer or the protection film may be defined as a base layer of the anti-reflector RPP.

The anti-reflector RPP according to one or more embodiments of the present disclosure may include color filters. The color filters have a specific array. The array of the color filters may be determined, based on light emitting colors of pixels included in the display panel DP. The anti-reflector RPP may further include a black matrix adjacent to the color filters.

The anti-reflector RPP according to one or more embodiments of the present disclosure may include a destructive interference structure. For example, the destructive interference structure may include a first reflective layer and a second reflective layer which are disposed in different layers. A first reflected light and a second reflected light respectively reflected from the first reflective layer and the second reflective layer, respectively, may cause the destructive interference, which results in a decrease in reflectance of an external light.

The window panel WP according to one or more embodiments of the present disclosure may include a glass substrate and/or a synthetic resin film. The window panel WP is not limited to being in a single layer. The window panel WP may include at least two films bonded by an adhesive member. In one or more embodiments, the window panel WP may further include a functional coating layer. The functional coating layer may include an anti-fingerprint layer, an anti-reflective layer, or a hard coating layer.

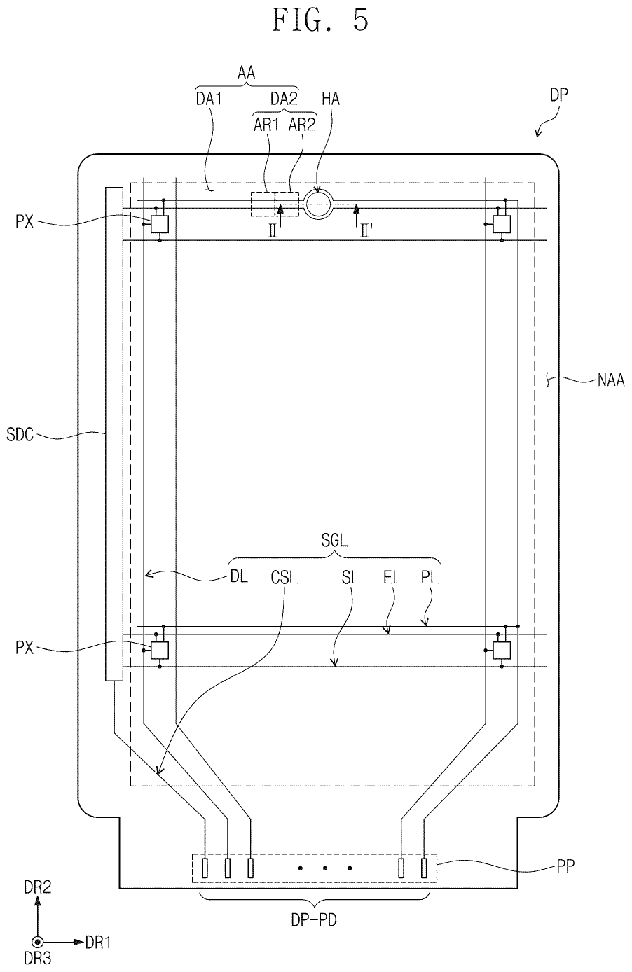

FIG. 5 is a plan view of a display panel according to one or more embodiments of the present disclosure.

Referring to FIG. 5, the display panel DP may include a scan driving circuit SDC, a plurality of signal lines (hereinafter referred to as the “signal lines”) SGL, a plurality of signal pads (hereinafter referred to as the “signal pads”) DP-PD, and a plurality of pixels (hereinafter referred to as the “pixels”) PX.

The scan driving circuit SDC generates a plurality of scan signals (hereinafter referred to as the “scan signals”) and sequentially outputs the scan signals to a plurality of scan lines (hereinafter referred to as the “scan lines”) SL to be described later. The scan driving circuit SDC may output any other control signals to the pixels PX, as well as the scan signals.

The scan driving circuit SDC may include a plurality of transistors formed through the same process as transistors in the pixels PX.

The signal lines SGL include the scan lines SL, data lines DL, a power line PL, light emitting control lines EL, and a control signal line CSL. The scan lines SL, the data lines DL, and the light emitting control lines EL are connected with relevant pixels of the pixels PX. The power line PL is commonly connected with the pixels PX. The control signal line CSL may provide the control signals to the scan driving circuit SDC. The power line PL may provide a voltage necessary for the operation of the pixels PX. The power line PL may include a plurality of lines which provide different voltages.

The signal pads DP-PD may be electrically connected to the data lines DL, the power line PL, and the control signal line CSL. The signal pads DP-PD are disposed to be adjacent to each other in the pad region PP defined in a partial region of the peripheral region NAA.

The active region AA may be defined as a region in which the pixels PX are disposed. A plurality of electronic elements are disposed in the active region AA. The electronic elements include an organic light emitting diode (OLED) disposed in each of the pixels PX and a pixel driving circuit disposed in each of the pixels PX and connected to the organic light emitting diode (OLED).

The display panel DP may include a first display region DA1 and a second display region DA2 defined in the display panel DP. The first display region DA1 and the second display region DA2 may form the active region AA of the display panel DP.

The resolution of the first display region DA1 may be different from the resolution of the second display region DA2. For example, the resolution of the second display region DA2 may be lower than the resolution of the first display region DA1.

The first display region DA1 may have a first light transmittance. The second display region DA2 may have a second light transmittance higher than the first light transmittance. Accordingly, an optical signal may be easily transmitted/received through electronic modules EM1 and EM2 disposed under the second display region DA2.

The second display region DA2 may include a first region AR1 and a second region AR2. The first electronic module EM1 (see FIG. 3) may be disposed under the display panel DP to correspond to the first region AR1. The second electronic module EM2 (see FIG. 3) may be disposed under the display panel DP to correspond to the second region AR2. Although FIG. 5 illustrates that the first region AR1 and the second region AR2 are adjacent to each other, the positions of the first region AR1 and the second region AR2 according to one or more embodiments of the present disclosure are not limited thereto. For example, the first region AR1 and the second region AR2 may be spaced (e.g., spaced apart) from each other while interposing the sensing hole HA between the first region AR1 and the second region AR2.

The sensing hole HA may be defined in the active region AA. The signal lines SGL may extend by detouring the sensing hole HA.

The signal pads DP-PD of the display panel DP may be electrically connected to the print circuit board FCB (see FIG. 3).

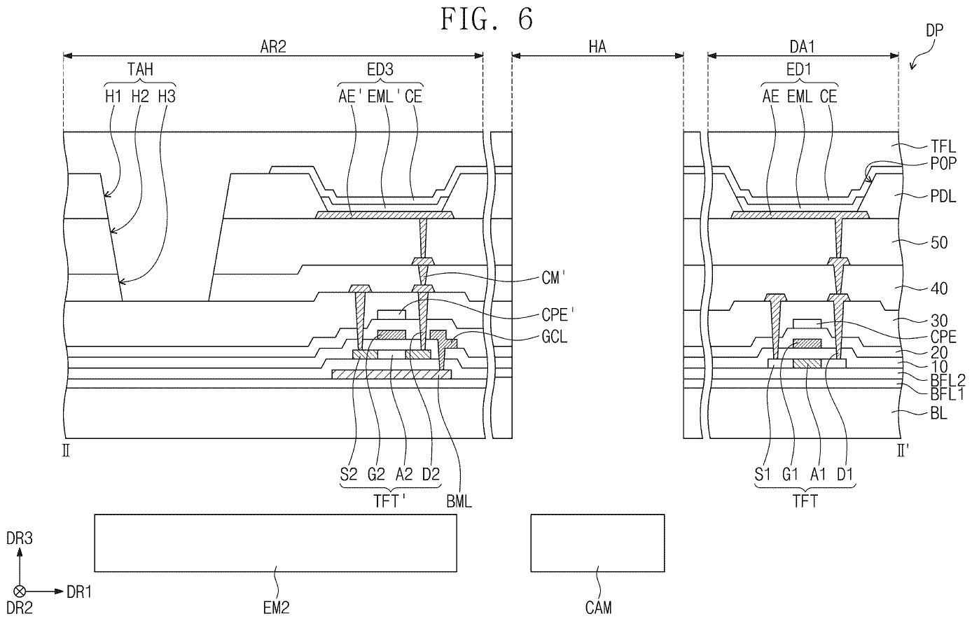

FIG. 6 is a cross-sectional view of a display panel taken along the line II-II′ illustrated in FIG. 5 according to one or more embodiments of the present disclosure.

Referring to FIGS. 5 and 6, a transistor TFT, a capacitor electrode CPE, and a light emitting element ED1 may be disposed in the first display region DA1. A transistor (or thin film transistor) TFT′, a capacitor electrode CPE′, and a light emitting element ED3 may be disposed in the second region AR2.

The second electronic module EM2 may be disposed under the second region AR2. As a transmissive hole TAH is defined in the second region AR2, the second electronic module EM2 may transmit/receive a signal through the transmissive hole TAH. The stack structure of the first region AR1 may be substantially identical to the stack structure of the second region AR2 illustrated in FIG. 6.

The display panel DP may include a plurality of insulating layers, a semiconductor pattern, a conductive pattern, a metal pattern, and a signal line. An insulating layer, a semiconductor layer, a conductive layer, and a metal layer are formed through a coating process and/or a deposition process. Thereafter, the insulating layer, the semiconductor layer, the conductive layer, and the metal layer may be selectively patterned through a photolithography process.

A first buffer layer BFL1 may be disposed on the base layer BL. The first buffer layer BFL1 may improve the coupling force between the base layer BL and a blocking pattern BML. The first buffer layer BFL1 may include at least one of a silicon oxide layer or a silicon nitride layer, and the silicon oxide layer and the silicon nitride layer may be alternately stacked.

The blocking pattern BML may be disposed on the first buffer layer BFL1. According to one or more embodiments, the first buffer layer BFL1 may be omitted. In this case, the blocking pattern BML may be provided on a top surface of the base layer BL.

The blocking pattern BML may be overlapped with the transistor TFT′. The blocking pattern BML may be overlapped with an active region (e.g., A1 of TFT and A2 of TFT′) to serve as a protection layer to prevent the active region from being degraded in electrical characteristic. In addition, the blocking pattern BML may protect the transistor TFT′ from light and/or moisture introduced from a lower portion of the base layer BL, during the manufacturing process of the electronic device. The blocking pattern BML may include a metal material having a lower light transmittance. For example, the blocking pattern BML may be a metal pattern formed by including molybdenum (Mo).

The light incident onto the blocking pattern BML may be reflected from the top surface or the bottom surface of the blocking pattern BML. The blocking pattern BML may prevent the characteristic of the thin film transistor TFT′ from being deteriorated by a light emitted from the second electronic module EM2.

The blocking pattern BML may be connected to a wiring GCL, which is disposed in a different layer, through a contact hole. The blocking pattern BML may receive a constant voltage or a signal from the wiring GCL. For example, the blocking pattern BML may receive a driving voltage or a scan signal. The blocking pattern BML may receive the constant voltage or the signal to reduce the possibility of the electrostatic discharge (ESD).

The blocking pattern BML may include aluminum (Al), platinum (Pt), palladium (Pd), silver (Ag), magnesium (Mg), gold (Au), neodymium (Nd), iridium (Ir), chromium (Cr), nickel (Ni), calcium (Ca), molybdenum (Mo), titanium (Ti), tungsten (W), and/or copper (Cu). The blocking pattern BML may be a single layer or a multi-layer including a material described above.

The second buffer layer BFL2 may be disposed on the blocking pattern BML and the first buffer layer BFL1. The second buffer layer BFL2 may cover an entire portion of the blocking pattern BML. A semiconductor pattern (e.g., AP1) is disposed on the second buffer layer BFL2. The semiconductor pattern may include a silicon semiconductor. The semiconductor pattern may include polysilicon or may include amorphous silicon. In addition, the semiconductor pattern may include a metal oxide semiconductor.

The semiconductor pattern may have an electrical characteristic varied depending on whether the semiconductor pattern is doped. The semiconductor pattern may include a doped region and an undoped region depending on a doping degree. The doped region may be doped with an N-type dopant or a P-type dopant. A P-type transistor includes a doped region doped with the P-type dopant.

The doped region may have a doping concentration greater than a concentration of the undoped region, and may have a conductivity greater than a conductivity of the undoped region. The doped region may substantially function as an electrode or a signal line. The undoped region may correspond to an active region (or a channel) of the transistor. In other words, a portion of the semiconductor pattern may be the active region (or channel) of the transistor, another portion of the semiconductor pattern may be a source (or an input electrode region) or drain (an output electrode region) of the transistor, and another portion of the semiconductor pattern may be a connection signal line (or connection electrode). The present disclosure is not limited thereto. Dopants may be doped into even the active region (or channel) of the transistor.

Sources S1 and S2, active regions A1 and A2, and drains D1 and D2 of the transistors TFT and TFT′, respectively, may be formed from the semiconductor pattern. A first insulating layer 10 may be disposed on the semiconductor pattern and the second buffer layer BFL2. Gates G1 and G2, which are provided in the transistors TFT and TFT′, respectively, may be disposed on the first insulating layer 10. A second insulating layer 20 may be disposed on the gates G1 and G2 and the first insulating layer 10.

Capacitor electrodes CPE and CPE′ may be disposed on the second insulating layer 20. The capacitor electrode CPE disposed on the gate G1 may define a capacitor, together with the gate G1. The capacitor electrode CPE′ disposed on the gate G2 may define a capacitor, together with the gate G2.

A third insulating layer 30 may be disposed on the second insulating layer 20. The third insulating layer 30 may cover the capacitor electrodes CPE and CPE′.

Electrodes connected to the sources S1 and S2 and the drains D1 and D2 may be disposed over the third insulating layer 30. A fourth insulating layer 40 may be disposed on the third insulating layer 30. The fourth insulating layer 40 may cover the electrodes connected to the sources S1 and S2 and the drains D1 and D2.

Connection electrodes CM′ may be disposed on the fourth insulating layer 40. The connection electrodes CM′ may be connected to the transistors TFT and TFT′ through contact holes, respectively. A fifth insulating layer 50 may be disposed on the fourth insulating layer 40. The fifth insulating layer 50 may cover the connection electrodes CM′.

The light emitting elements ED1 and ED3 may include first electrodes AE and AE′, light emitting layers EML and EML′, and a second electrode CE.

The first electrodes AE and AE′ may be disposed on the fifth insulating layer 50. The first electrodes AE and AE′ may be anode electrodes. The pixel defining film PDL may be disposed on the first electrodes AE and AE′ and the fifth insulation layer 50. An opening POP may be defined in the pixel defining film PDL to expose a specific portion of each of the first electrodes AE and AE′.

The pixel defining film PDL may include a polymer resin. For example, the pixel defining film (PDL) may be formed by including a polyacrylate-based resin or a polyimide-based resin. In addition, the pixel defining film PDL may further include an inorganic material in addition to the polymer resin. In one or more embodiments, the pixel defining film PDL may be formed by including a light absorbing material, or may be formed by including a black pigment or a black dye. The pixel defining film PDL formed by including the black pigment or the black dye may implement a black pixel defining film. When the pixel defining film PDL is formed, carbon black may be used as the black pigment or the black dye, but the present disclosure is not limited thereto.

The light emitting layers EML and EML′ may be disposed on the first electrodes AE and AE′, respectively. The light emitting layer EML may be disposed in a region corresponding to the opening POP. Each of the light emitting layers EML and EML′ may include an organic material and/or an inorganic material.

The second electrode CE may be disposed on the light emitting layers EML and EML′. The second electrode CE may be a cathode electrode. The second electrode CE may be provided in the form of a common layer.

The transmissive hole TAH may be defined in each of the fourth insulating layer 40, the fifth insulating layer 50, and the pixel defining film PDL. The transmissive hole TAH may be formed to expose a top surface of the third insulating layer 30. The transmissive hole TAH may be formed, as a first hole H1 in the pixel defining film PDL, a second hole H2 in the fifth insulating layer 50, and a third hole H3 in the fourth insulating layer 40 that are overlapped with each other. The first to third holes H1, H2, and H3 may be formed individually through a separate process, or may be formed concurrently (e.g., simultaneously) through the same process. However, this is provided only for the illustrative purpose. For example, the configuration of the transmissive hole TAH according to one or more embodiments of the present disclosure is not limited thereto. For example, the transmissive hole TAH may be provided in various forms, as long as the various forms are components to increase a light transmittance of the second region AR2. The second electronic module EM2 may transmit or receive a signal through the transmissive hole TAH.

An encapsulating layer TFL may be disposed on the second electrode CE and the pixel defining film PDL. The encapsulating layer TFL may include an inorganic layer, an organic layer, and an inorganic layer sequentially stacked, and layers constituting the encapsulating layer TFL are not limited thereto.

The inorganic layers may protect the transistors TFT and TFT′ from moisture and/or oxygen, and the organic layer may protect the transistors TFT and TFT′ from foreign substances such as dust particles. The inorganic layers may include a silicon nitride layer, a silicon oxynitride layer, a silicon oxide layer, a titanium oxide layer, and/or an aluminum oxide layer. The organic layer may include an acrylic-based organic layer, but the present disclosure is not limited thereto.

The sensing hole HA may be formed through the display panel DP. The camera module CAM may be disposed to correspond to the sensing hole HA. In this case, an area of the sensing hole HA may be provided to be larger than an area for disposing the camera module CAM.

The camera module CAM may need a light transmittance higher than a light transmittance required by the first electronic module EM1, and the second electronic module EM2. The sensing hole HA may prevent the function of the camera module CAM from being degraded.

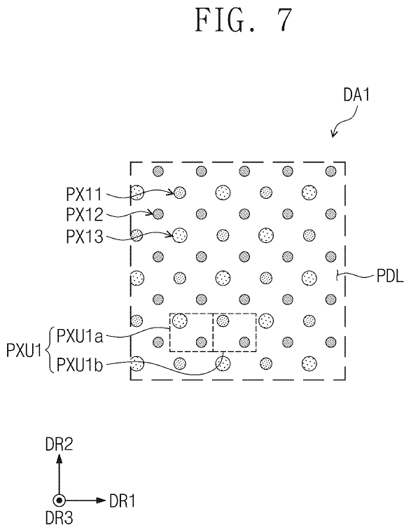

FIG. 7 is a plan view of a first display region according to one or more embodiments of the present disclosure.

Referring to FIGS. 5 and 7, the display panel DP may include the plurality of pixels PX.

The plurality of pixels PX may include a plurality of first pixels PX11, PX12, and PX13. The plurality of first pixels PX11, PX12, and PX13 may be disposed in the first display region DA1. The plurality of first pixels PX11, PX12, and PX13 may include a (1-1)-th color pixel PX11, a (1-2)-th color pixel PX12, and a (1-3)-th color pixel PX13. The (1-1)-th color pixel PX11 may be a red light emitting pixel, the (1-2)-th color pixel PX12 may be a green light emitting pixel, and the (1-3)-th color pixel PX13 may be a blue light emitting pixel.

The plurality of first pixels PX11, PX12, and PX13 may define a first pixel unit PXU1. The first pixel unit PXU1 may include a first sub-pixel unit PXU1a and a second sub-pixel unit PXU1b. The first sub-pixel unit PXU1a and the second sub-pixel unit PXU1b may be alternately arranged along the first direction DR1 and the second direction DR2.

The first sub-pixel unit PXU1a may include the (1-3)-th color pixel PX13 and the (1-2)-th color pixel PX12. The second sub-pixel unit PXU1b may include the (1-1)-th color pixel PX11 and the (1-2)-th color pixel PX12.

Each of the first pixels PX11, PX12, and PX13 may have a shape corresponding to a shape of a light emitting region defined in the light emitting element, when viewed in a plan view. The light emitting region may be a region defined by the pixel defining film PDL.

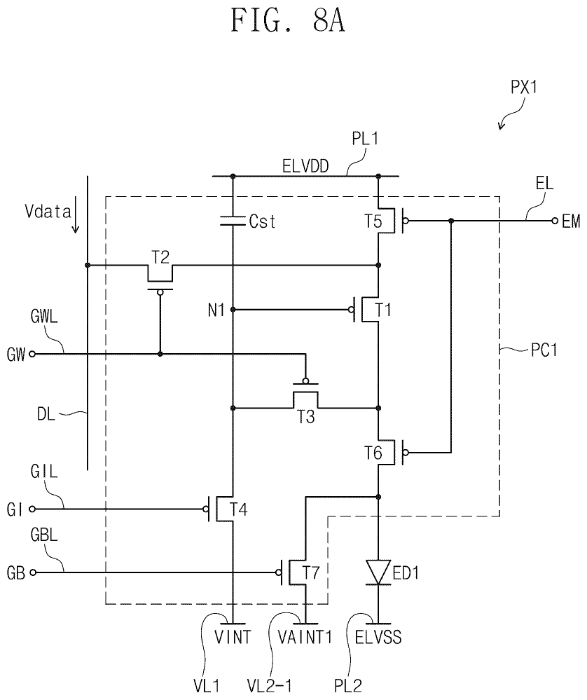

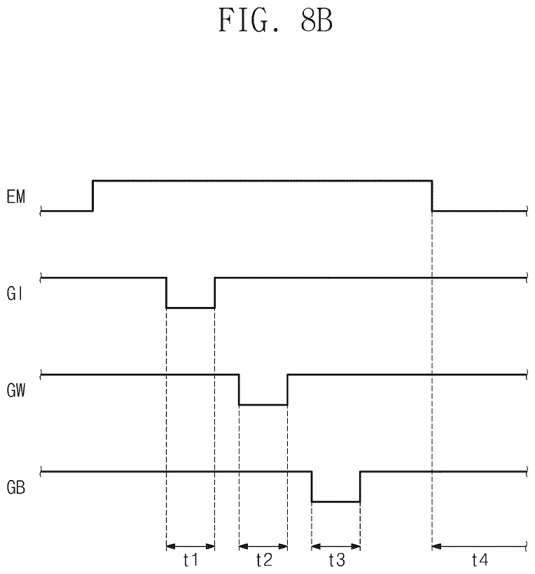

FIG. 8A is an equivalent circuit diagram of a first pixel according to one or more embodiments of the present disclosure.

Referring to FIGS. 7 and 8A, the plurality of scan lines SL (see FIG. 5) may include an initializing scan line GIL, a write scan line GWL, and a black scan line GBL.

The initializing scan line GIL may provide an initializing scan signal GI to each of the plurality of pixels PX. The write scan line GWL may provide a write scan signal GW to each of the plurality of pixels PX. The black scan line GBL may provide a black scan signal GB to each of the plurality of pixels PX. The light emitting control line EL may provide a light emitting control signal EM to each of the plurality of pixels PX. The data line DL may provide a data signal Vdata to each of the plurality of pixels PX. The data signal Vdata may have a voltage level corresponding to an image signal input to the electronic device 1000 (see FIG. 3).

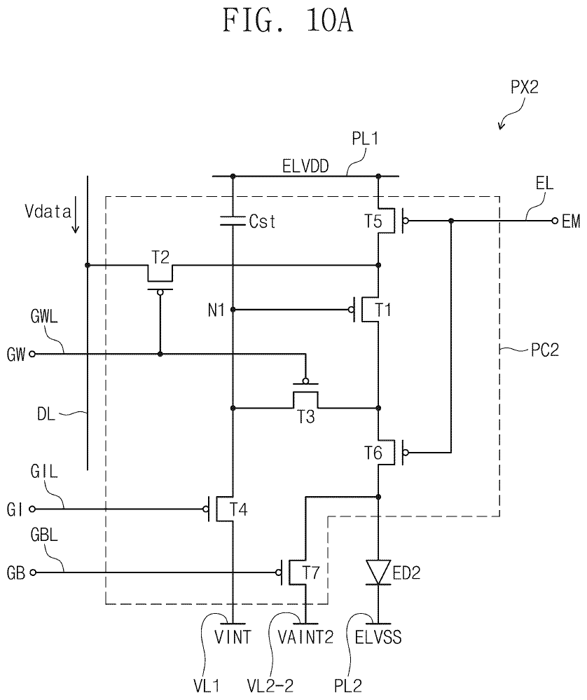

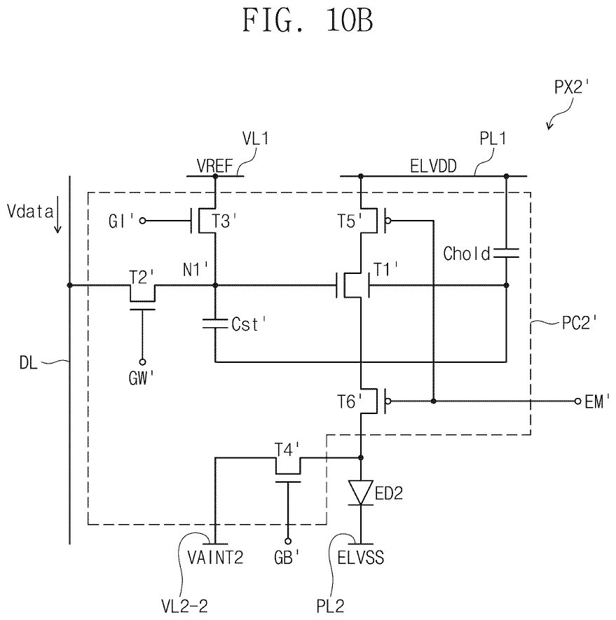

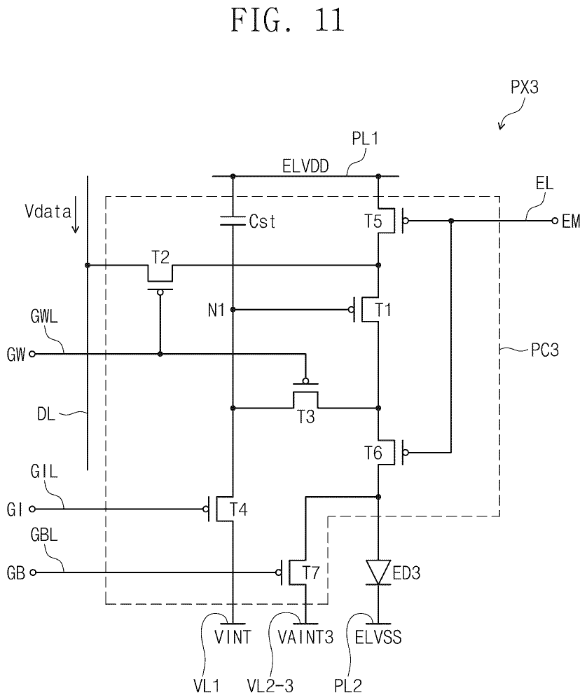

The power line PL (see FIG. 5) may include a first power line PL1, a second power line PL2, a first initializing voltage line VL1, a (2-1)-th initializing voltage line VL2-1, a (2-2)-th initializing voltage line VL2-2 (see FIGS. 10A-10B), and a (2-3)-th initializing voltage line VL2-3 (see FIG. 11).

The first power line PL1 may transfer first power ELVDD to each of the plurality of pixels PX. For example, the first power ELVDD may have a voltage level of about 4.6 V (volt).

The second power line PL2 may transfer second power ELVSS, which has a voltage level lower than the voltage level of the first power ELVDD, to each of the plurality of pixels PX. For example, the second power ELVSS may have the voltage level of about −2.1 V (volt).

The first initializing voltage line VL1 may transfer a first initializing voltage VINT to each of the plurality of pixels PX.

The plurality of pixels PX may include a first pixel PX1. The first pixel PX1 may be one of the plurality of first pixels PX11, PX12, and PX13.

The (2-1)-th initializing voltage line VL2-1 may transfer a (2-1)-th initializing voltage VAINT1 to the first pixel PX1.

The first pixel PX1 may include a light emitting element ED1 and a pixel circuit PC1. The light emitting element ED1 may be a light emitting diode (that is, an LED). According to one or more embodiments of the present disclosure, the light emitting element ED1 may be an organic light emitting diode (OLED) including an organic light emitting layer, but the present disclosure is not limited thereto. The pixel circuit PC1 may control an amount of current flowing through the light emitting element ED1, to correspond to the data signal Vdata. The light emitting element ED1 may emit a light having a specific luminance to correspond to an amount of current provided from the pixel circuit PC1.

The pixel circuit PC1 may include first to seventh transistors T1, T2, T3, T4, T5, T6, and T7, and at least one capacitor Cst. A configuration of the pixel circuit PC1 according to the present disclosure is not limited to an embodiment illustrated in FIG. 8A. The pixel circuit PC1 illustrated in FIG. 8A is provided only for the illustrative purpose. For example, the configuration of the pixel circuit PC1 may be modified and implemented.

At least one of the first to seventh transistors T1, T2, T3, T4, T5, T6, and T7 may be a transistor having a low-temperature polycrystalline silicon (LTPS) semiconductor layer. However, this is provided only for the illustrative purpose. For example, at least one of the first to seventh transistors T1, T2, T3, T4, T5, T6, and T7 according to one or more embodiments of the present disclosure may be a transistor having a low-temperature polycrystalline silicon (LTPS) semiconductor layer, and remaining transistors of the first to seventh transistors T1, T2, T3, T4, T5, T6, and T7 may be transistors having an oxide semiconductor layer.

The first to seventh transistors T1, T2, T3, T4, T5, T6, and T7 may be P-type transistors.

The first transistor T1 is connected between the first power line PL1 to receive the first power ELVDD and the light emitting element ED1. The first transistor T1 includes a first electrode connected to the first power line PL1 through the fifth transistor T5, a second electrode connected to an anode electrode of the light emitting element ED1 through the sixth transistor T6, and a third electrode (e.g., a gate electrode) connected to a first terminal (e.g., a first node N1) of the capacitor Cst. The first transistor T1 may receive the data signal Vdata transmitted through the data line DL depending to the switching operation of the second transistor T2 and may supply the driving current to the light emitting element ED1. The first transistor T1 may be referred to as a “driving transistor T1”.

The second transistor T2 is connected between the data line DL and the first electrode of the first transistor T1. The second transistor T2 includes a first electrode connected to the data line DL, a second electrode connected to the first electrode of the first transistor T1, and a third electrode (e.g., a gate electrode) connected to the write scan line GWL. The second transistor T2 may be turned on in response to the write scan signal GW, which is received through the write scan line GWL, to transmit the data signal Vdata, which is received through the data line DL, to the first electrode of the first transistor T1. The second transistor T2 may be referred to as a “switch transistor T2”.

The third transistor T3 is connected between the second electrode of the first transistor T1 and the first node N1. The third transistor T3 includes a first electrode connected to the third electrode (e.g., the gate electrode) of the first transistor T1, a second electrode connected to the second electrode of the first transistor T1, and a third electrode (e.g., a gate electrode) connected to the write scan line GWL. The third transistor T3 may be turned on in response to the write scan signal GW transmitted through the write scan line GWL to connect the third electrode (e.g., the gate electrode) of the first transistor T1 to the second electrode of the first transistor T1, such that the first transistor T1 is diode-connected.

The fourth transistor T4 is connected between the first initializing line VL1, which receives the first initializing voltage VINT, and the first node N1. The fourth transistor T4 includes a first electrode connected to the first initializing voltage line VL1 to transmit the first initializing voltage VINT, a second electrode connected to the first node N1, and a third electrode (e.g., a gate electrode) connected to the initializing scan line GIL. The fourth transistor T4 is turned on in response to the initializing scan signal GI received through the initializing scan line GIL. The fourth transistor T4 is turned on to transmit the first initializing voltage VINT to the first node N1 such that a potential at the third electrode (e.g., the gate electrode) of the first transistor T1 (that is, a potential at the first node N1) is initialized.

The fifth transistor T5 includes a first electrode connected to the first power line PL1, a second electrode connected to the first electrode of the first transistor T1, and a third electrode (e.g., the gate electrode) connected to the light emitting control line EL.

The sixth transistor T6 may include a first electrode connected to the second electrode of the first transistor T1, a second electrode connected to the anode of the light emitting element ED1, and a third electrode (e.g., a gate electrode) connected to the light emitting control line EL.

The fifth and sixth transistors T5 and T6 are concurrently (e.g., simultaneously) turned on in response to the light emitting control signal EM received through the light emitting control line EL. The first power ELVDD applied through the turned-on fifth transistor T5 may be transmitted to the light emitting element ED1 through the sixth transistor T6 after passing through the first transistor T1.

The seventh transistor T7 of the first pixel PX1 includes a first electrode connected to the (2-1)-th initializing voltage line VL2-1 to transmit the (2-1)-th initializing voltage VAINT1, a second electrode connected to the second electrode of the sixth transistor T6, and a third electrode (e.g., a gate electrode) connected to the black scan line GBL. The (2-1)-th initializing voltage VAINT1 may have a voltage level different from the voltage level of the first initializing voltage VINT. For example, the (2-1)-th initializing voltage VAINT1 may have a voltage level lower than a voltage level of the first initializing voltage VINT. The (2-1)-th initializing voltage VAINT1 may have a voltage level equal to a voltage level of the second power ELVSS. For example, the (2-1)-th initializing voltage VAINT1 may have a voltage level of about −2.1 V.

According to the present disclosure, when the seventh transistor T7 is turned on, the anode electrode of the light emitting element ED1 may be initialized to the (2-1)-th initializing voltage VAINT1. When the anode electrode of the light emitting element ED1 is initialized to the (2-1)-th initializing voltage VAINT1 through the seventh transistor T7, the black characteristic of the first pixel PX1 may be improved. In other words, a phenomenon, in which the light emitting element ED1 emits a light due to a current leaked from the first transistor T1, may be prevented, such that the pixel PX1 accurately displays a black gray level. Accordingly, the electronic device 1000 (see FIG. 2) may be provided with improved display quality.

The first terminal of the capacitor Cst is connected to the third electrode (e.g., the gate electrode) of the first transistor T1 or the first node N1, and a second terminal, which is opposite to the first terminal, of the capacitor Cst is connected to the first power line PL1.

A cathode of the light emitting element ED may be connected to the second power line PL2 to transmit the second power ELVSS.

FIG. 8B is a timing diagram to describe the operation of a plurality of pixels according to one or more embodiments of the present disclosure.

Referring to FIGS. 5, 8A, and 8B, the display panel DP may operate in a unit of a frame duration to display the image IM (see FIG. 2). One frame duration may include first to fourth periods t1, t2, t3, and t4. The first to third periods t1, t2, and t3 may be referred to as non-emission periods, and the fourth period t4 may be referred to as a light emitting period.

The initializing scan signal GI may have an active level for the first period t1. The active level of the initializing scan signal GI may be a low level.

The light emitting control signal EM, the write scan signal GW, and the black scan signal GB may have a non-active level for the first period t1. The non-active level of each of the light emitting control signal EM, the write scan signal GW, and the black scan signal GB may be a high level.

The fourth transistor T4 may be turned on in response to the initializing scan signal GI. The first initializing voltage VINT may be provided to the first node N1 through the fourth transistor T4.

The gate electrode of the first transistor T1 may be initialized to the first initializing voltage VINT for the first period t1. In other words, the voltage at the first node N1 may be changed to the first initializing voltage VINT from the data signal Vdata for a previous frame duration.

The first period t1 may be referred to as a first initializing period.

The write scan signal GW may have an active level for the second period t2. The active level of the write scan signal GW may be a low level.

Each of the light emitting control signal EM, the initializing scan signal GI, and the black scan signal GB may have a non-active level for the second period t2.

The second transistor T2 and the third transistor T3 may be turned on in response to the write scan signal GW.

The data signal Vdata provided through the data line DL may be provided to the first node N1 through the diode-connected first transistor T1.

The capacitor Cst may store a differential voltage between the first node N1 and the first power line PL1. The capacitor Cst may be referred to as a storage capacitor.

The second period t2 may be referred to as a write period.

The black scan signal GB may have an active level for the third period t3. The active level of the black scan signal GB may be a low level. For example, the low level of the black scan signal GB may be about −8 V.

Each of the light emitting control signal EM, the initializing scan signal GI, and the write scan signal GW may have a non-active level for the third period t3.

The seventh transistor T7 of the first pixel PX1 may be connected to the (2-1)-th initializing voltage line VL2-1. The seventh transistor T7 may be turned on in response to the black scan signal GB.

The anode electrode of the light emitting element ED1 may be initialized to the (2-1)-th initializing voltage VAINT1.

The third period t3 may be referred to as a “second initializing period”.

The light emitting control signal EM may have an active level for the fourth period t4. The active level of the light emitting control signal EM may be a low level.

Each of the initializing scan signal GI, the write scan signal GW, and the black scan signal GB may have a non-active level for the fourth period t4.

Each of the fifth transistor T5 and the sixth transistor T6 may be turned on in response to the light emitting control signal EM.

As the fifth transistor T5 and the sixth transistor T6 are turned on, a current path may be formed from the first power line PL1 to the second power line PL2 through the fifth transistor T5, the first transistor T1, the sixth transistor T6, and the light emitting element ED1. In other words, the driving current may flow through the first power line PL1, the fifth transistor T5, the first transistor T1, the sixth transistor T6, the light emitting element ED1, and the second power line PL2.

The fourth period t4 may be referred to as a light emitting period.

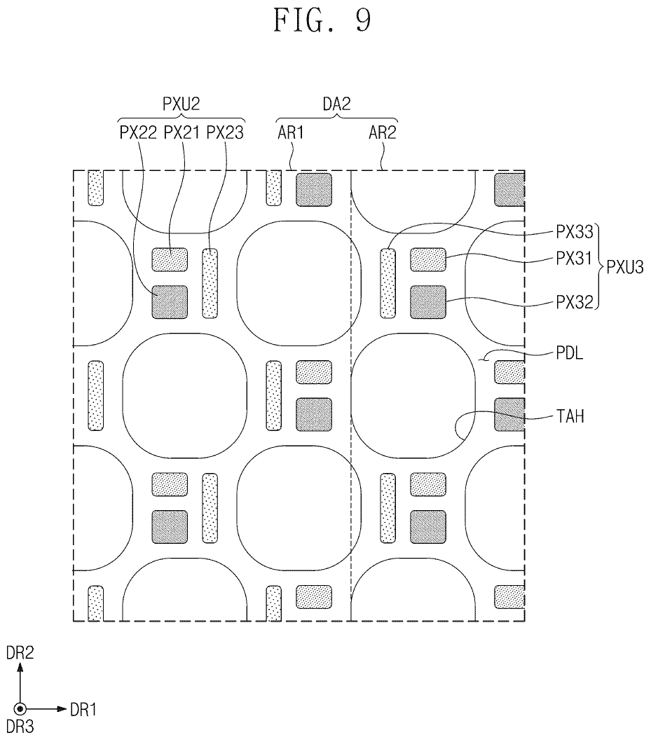

FIG. 9 is a plan view of a second display region according to one or more embodiments of the present disclosure.

Referring to FIGS. 5, 7, and 9, the display panel DP may include the plurality of pixels PX. The second display region DA2 may have a light transmittance higher than the light transmittance of the first display region DA1. The transmissive hole TAH may be defined in the second display region DA2. A plurality of transmissive holes TAH may be provided in the second display region DA2. The transmissive holes TAH may be defined by the pixel defining film PDL.

The shape of each of the transmissive holes TAH may not be a circle. For example, each of the transmissive holes TAH may have, a polygonal shape, an amorphous shape including a curved line or a linear line, or an amorphous shape including curved lines having different curvatures, as long as the shape is formed using a closed line. Each of the transmissive holes TAH may have various shapes, and the present disclosure is not limited to any one embodiment.

The plurality of pixels PX may include a plurality of second pixels PX21, PX22, and PX23, and a plurality of third pixels PX31, PX32, and PX33.

The plurality of second pixels PX21, PX22, and PX23 may be disposed in the first region AR1. The plurality of second pixels PX21, PX22, and PX23 may include a (2-1)-th color pixel PX21, a (2-2)-th color pixel PX22, and a (2-3)-th color pixel PX23.

The (2-1)-th color pixel PX21 may be a red light emitting pixel, the (2-2)-th color pixel PX22 may be a green light emitting pixel, and the (2-3)-th color pixel PX23 may be a blue light emitting pixel.

The plurality of second pixels PX21, PX22, and PX23 may define a second pixel unit PXU2.

The plurality of third pixels PX31, PX32, and PX33 may be disposed in the second region AR2. The plurality of third pixels PX31, PX32, and PX33 may include a (3-1)-th color pixel PX31, a (3-2)-th color pixel PX32, and a (3-3)-th color pixel PX33. The (3-1)-th color pixel PX31 may be a red light emitting pixel, the (3-2)-th color pixel PX32 may be a green light emitting pixel, and the (3-3)-th color pixel PX33 may be a blue light emitting pixel.

Each of the second pixels PX21, PX22, and PX23, and the third pixels PX31, PX32, and PX33 may have a shape corresponding to a shape of a light emitting region defined in the light emitting element, when viewed in a plan view.

According to one or more embodiments, the arrangement rule of the first pixels PX11, PX12, and PX13 disposed in the first display region DA1 or the shape of the light emitting region defined in each of the first pixels PX11, PX12, and PX13 may be different from the arrangement rules of the plurality of second pixels PX21, PX22, and PX23, and the plurality of third pixels PX31, PX32, and PX33 disposed in the second display region DA2, or the shape of the light emitting region defined in each of the second pixels PX21, PX22, and PX23 and the third pixels PX31, PX32, and PX33.

For example, the number of a plurality of first pixels PX11, PX12, and PX13 disposed in a reference region of the first display region DA1 may be greater than the number of the plurality of second pixels PX21, PX22, and PX23 or the plurality of third pixels PX31, PX32, and PX33 disposed in a reference region of the second display region DA2. Alternatively, the area of the plurality of first pixels PX11, PX12, and PX13 disposed in the reference region of the first display region DA1 may be larger than the area of the plurality of second pixels PX21, PX22, PX23 or the plurality of third pixels PX31, PX32, and PX33 disposed in the reference region of the second display region DA2. Accordingly, when the same luminance is implemented within the reference region, the size of each of the plurality of second pixels PX21, PX22, PX23 and the plurality of third pixels PX31, PX32, and PX33, which should emit a brighter light, may be provided to be larger than the size of each of the plurality of first pixels PX11, PX12, and PX13, thereby compensating for the lifespans of the plurality of second pixels PX21, PX22, PX23 and the plurality of third pixels PX31, PX32, and PX33.

However, this is provided only for the illustrative purpose. For example, in the display panel according to one or more embodiments of the present disclosure, the plurality of first pixels PX11, PX12, and PX13, the plurality of second pixels PX21, PX22, PX23, and the plurality of third pixels PX31, PX32, and PX33 may have the same shape and/or the same arrangement rule, and the present disclosure is not limited to one embodiment.

According to one or more embodiments of the present disclosure, the first region AR1 and the second region AR2 may have the same arrangement configuration, except for connection relations that the (2-2)-th initializing voltage line VL2-2 (see FIG. 10A) is connected to the plurality of second pixels PX21, PX22, and PX23, and the (2-3)-th initializing voltage line VL2-3 (see FIG. 11) is connected to the plurality of the third pixels PX31, PX32, and PX33. The details thereof will be described below.

FIG. 10A is an equivalent circuit diagram of a second pixel according to one or more embodiments of the present disclosure. In the following description made with reference to FIG. 10A, the components that have been described with reference to FIG. 8A will be assigned with the same reference numerals, and the details thereof will be omitted.

Referring to FIGS. 9 and 10A, the plurality of pixels PX (see FIG. 5) may include a second pixel PX2. The second pixel PX2 may be one of the plurality of second pixels PX21, PX22, and PX23.

The (2-2)-th initializing voltage line VL2-2 may transfer the (2-2)-th initializing voltage VAINT2 to the second pixel PX2.

The second pixel PX2 may include a light emitting element ED2 and a pixel circuit PC2.

The seventh transistor T7 of the second pixel PX2 includes a first electrode connected to the (2-2)-th initializing voltage line VL2-2 to transmit the (2-2)-th initializing voltage VAINT2, a second electrode connected to the second electrode of the sixth transistor T6, and a third electrode (e.g., a gate electrode) connected to the black scan line GBL. The (2-2)-th initializing voltage VAINT2 may have a voltage level different from the voltage level of the first initializing voltage VINT. For example, the (2-2)-th initializing voltage VAINT2 may have a voltage level lower than a voltage level of the first initializing voltage VINT.

The (2-2)-th initializing voltage VAINT2 may have a voltage level equal to or lower than a voltage level of the (2-1)-th initializing voltage VAINT1 (see FIG. 8A).

When the second electronic module EM2 (see FIG. 3), is driven, the (2-1)-th initializing voltage VAINT1 (see FIG. 8A) may be different from the (2-2)-th initializing voltage VAINT2. The (2-1)-th initializing voltage VAINT1 (see FIG. 8A) may have a voltage level higher than a voltage level of the (2-2)-th initializing voltage VAINT2. For example, the (2-2)-th initializing voltage VAINT2 may have a voltage level of about −3.4 V.

When the second electronic module EM2 (see FIG. 3) is not driven, each of the (2-1)-th initializing voltage VAINT1 (see FIG. 8A) and the (2-2)-th initializing voltage VAINT2 may have an equal voltage level. For example, the (2-2)-th initializing voltage VAINT2 may have a voltage level of about −2.1 V.

According to the present disclosure, when the seventh transistor T7 is turned on, the anode electrode of the light emitting element ED2 may be initialized to the (2-2)-th initializing voltage VAINT2. When the anode electrode of the light emitting element ED2 is initialized to the (2-2)-th initializing voltage VAINT2 through the seventh transistor T7, the black characteristic of the second pixel PX2 may be improved. In other words, a phenomenon, in which the light emitting element ED2 emits light due to a current leaked from the first transistor T1, may be prevented, such that the second pixel PX2 accurately displays a black gray level. Accordingly, the electronic device 1000 (see FIG. 2) may have improved display quality.

FIG. 10B is an equivalent circuit diagram of a second pixel according to one or more embodiments of the present disclosure. In the following description made with reference to FIG. 10B, the components that have been described with reference to FIG. 10A will be assigned with the same reference numerals, and the details thereof will be omitted.

Referring to FIGS. 9 and 10B, the second pixel PX2′ may include the light emitting element ED2 and a pixel circuit PC2′. Although FIG. 10B illustrates the equivalent circuit diagram of the second pixel PX2′, the equivalent circuit diagram illustrated in FIG. 10B may be applied to the plurality of pixels PX disposed in the second display region DA2.

The pixel circuit PC2′ may include first to sixth transistors T1′, T2′, T3′, T4′, T5′, and T6′, a first capacitor Cst′, and a second capacitor Chold.

The first to fourth transistors T1′, T2′, T3′, and T4′ may be transistors having an oxide semiconductor layer, and the fifth and sixth transistors T5′ and T6′ may transistors having a low-temperature polycrystalline silicon (LTPS) semiconductor layer.

The first to fourth transistors T1′, T2′, T3′, and T4′ are N-type transistors, and the fifth and sixth transistors T5′ and T6′ are P-type transistors.

Although FIG. 10B illustrates that the first transistor T1′ includes two gates, and each of the second to sixth transistors T2′, T3′, T4′, T5′, and T6′ includes one gate, the present disclosure is not limited thereto. For example, the second to sixth transistors T2′, T3′, T4′, T5′, and T6′ may include two gates.

The first transistor T1′ is connected between the first power line PL1, which receives the first power ELVDD, and the light emitting element ED2. The first transistor T1′ includes a first electrode connected to the first power line PL1 through the fifth transistor T5′, a second electrode connected to an anode electrode of the light emitting element ED2 through the sixth transistor T6′, and a third electrode (e.g., a gate electrode) connected to a first terminal (e.g., a first node N1′) of the capacitor Cst′. The first transistor T1′ may receive the data signal Vdata transmitted through the data line DL depending to the switching operation of the second transistor T2′ and may supply a driving current to the light emitting element ED2.

The second transistor T2′ is connected between the data line DL and the third electrode (e.g., the gate electrode) of the first transistor T1′ or the first node N1′. The second transistor T2′ includes a first electrode connected to the data line DL, a second electrode connected to the first node N1′, and a third electrode (e.g., a gate electrode) connected to the write scan line GW′. The second transistor T2′ may be turned on in response to the write scan signal GW′, to transmit the data signal Vdata, which is received through the data line DL, to the first node N1′.

The third transistor T3′ is connected between the first initializing line VL1, which receives the first initializing voltage VREF, and the first node N1′. The third transistor T3′ includes a first electrode connected to the first initializing voltage line VL1, a second electrode connected to the third electrode (e.g., the gate electrode) of the first transistor T1′ or the first node N1′, and a third electrode (e.g., a gate electrode) to receive the initializing scan signal GI′. The third transistor T3′ is turned on in response to the initializing scan signal GI′ to transmit the first initializing voltage VREF to the first node N1′ such that a potential at the third electrode of the first transistor T1′ (that is, a potential of the first node N1′) is initialized.

The fourth transistor T4′ of the second pixel PX2′ includes a first electrode connected to the (2-2)-th initializing voltage line VL2-2 to transmit the (2-2)-th initializing voltage VAINT2, a second electrode connected to the second electrode of the sixth transistor T6′, and a third electrode (e.g., a gate electrode) to receive the black scan signal GB′.

When the fourth transistor T4′ is turned on, the anode electrode of the light emitting element ED2 may be initialized to the (2-2)-th initializing voltage VAINT2. When the anode electrode of the light emitting element ED2 is initialized to the (2-2)-th initializing voltage VAINT2 through the fourth transistor T4′, the black characteristic of the second pixel PX2 may be improved. In other words, a phenomenon, in which the light emitting element ED2 emits a light due to a current leaked from the first transistor T1′, may be prevented, such that the pixel PX2 accurately displays a black gray level.

The fourth transistor T4′ of FIG. 10B may perform a function substantially the same as that of the seventh transistor T7 (see FIG. 10A).

The fifth transistor T5′ includes a first electrode connected to the first power line PL1, a second electrode connected to the first electrode of the first transistor T1′, and a third electrode (e.g., a gate electrode) to receive the light emitting control signal EM′.

The sixth transistor T6′ may include a first electrode connected to the second electrode of the first transistor T1′, a second electrode connected to the anode of the light emitting element ED2, and a third electrode (e.g., a gate electrode) to receive the light emitting control signal EM′.

The fifth and sixth transistors T5′ and T6′ are concurrently (e.g., simultaneously) turned on in response to the light emitting control signal EM′. The first power ELVDD applied through the turned-on fifth transistor T5′ may be transmitted to the light emitting element ED2 through the sixth transistor T6′ after passing through the first transistor T1′.

The first terminal of the first capacitor Cst′ is connected to the third electrode (e.g., the gate electrode) of the first transistor T1′ or the first node N1′, and a second terminal, which is opposite to the first terminal, of the first capacitor Cst′ is connected to the second electrode of the first transistor T1′. The first capacitor Cst′ may be referred to as a storage capacitor Cst′.

A first terminal of the second capacitor Chold is connected to the second gate of the first transistor T1′, and a second terminal, which is opposite to the first terminal, of the capacitor Chold is connected to the first power line PL1. The second capacitor Chold may be referred to as a hold capacitor Chold.

FIG. 11 is an equivalent circuit diagram of a third pixel according to one or more embodiments of the present disclosure. In the following description made with reference to FIG. 11, the components that have been described with reference to FIG. 8A will be assigned with the same reference numerals, and the details thereof will be omitted.

Referring to FIGS. 9 and 11, the plurality of pixels PX (see FIG. 5) may include a third pixel PX3. The third pixel PX3 may be one of the plurality of third pixels PX31, PX32, and PX33.

The (2-3)-th initializing voltage line VL2-3 may transmit a (2-3)-th initializing voltage VAINT3 to the third pixel PX3.

The third pixel PX3 may include a light emitting element ED3 and a pixel circuit PC3.

The seventh transistor T7 of the third pixel PX3 includes a first electrode connected to the (2-3)-th initializing voltage line VL2-3 to transmit the (2-3)-th initializing voltage VAINT3, a second electrode connected to the second electrode of the sixth transistor T6, and a third electrode (e.g., a gate electrode) connected to the black scan line GBL. The (2-3)-th initializing voltage VAINT3 may have a voltage level different from the voltage level of the first initializing voltage VINT. For example, the (2-3)-th initializing voltage VAINT3 may have a voltage level lower than a voltage level of the first initializing voltage VINT. The (2-3)-th initializing voltage VAINT3 may have a voltage level equal to or lower than a voltage level of the (2-1)-th initializing voltage VAINT1 (see FIG. 8A).

When the second electronic module EM2 (see FIG. 3) is driven, the (2-1)-th initializing voltage VAINT1 (see FIG. 8A), the (2-2)-th initializing voltage VAINT2 (see FIG. 10A), and the (2-3)-th initializing voltage VAINT3 may be different from each other. The (2-2)-th initializing voltage VAINT2 (see FIG. 10A) may have a voltage level higher than a voltage level of the (2-3)-th initializing voltage VAINT3. For example, the (2-3)-th initializing voltage VAINT3 may have a voltage level of about −3.8 V.

When the second electronic module EM2 (see FIG. 3) is not driven, the (2-1)-th initializing voltage VAINT1 (see FIG. 8A), the (2-2)-th initializing voltage VAINT2 (see FIG. 10A), and the (2-3)-th initializing voltage VAINT3 may have the same voltage level. For example, the (2-3)-th initializing voltage VAINT3 may have a voltage level of about −2.1 V.

According to the present disclosure, when the seventh transistor T7 is turned on, the anode electrode of the light emitting element ED3 may be initialized to the (2-3)-th initializing voltage VAINT3. When the anode electrode of the light emitting element ED3 is initialized to the (2-3)-th initializing voltage VAINT3 through the seventh transistor T7, the black characteristic of the third pixel PX3 may be improved. In other words, a phenomenon, in which the light emitting element ED3 emits a light due to a current leaked from the first transistor T1, may be prevented, such that the pixel PX3 accurately displays a black gray level. Accordingly, the electronic device 1000 (see FIG. 2) may be provided with improved display quality.

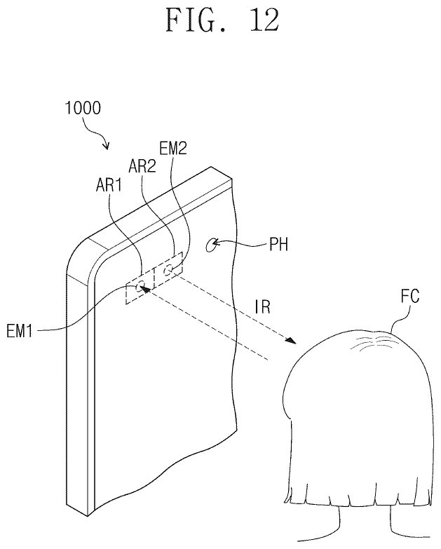

FIG. 12 illustrates the operation of an electronic device according to one or more embodiments of the present disclosure.

Referring to FIGS. 3, 5, and 12, the display panel DP may include the first display region DA1, which has a first light transmittance, and the second display region DA2, which has a second light transmittance higher than the first light transmittance, defined in the display panel DP.

The second display region DA2 may include the first region AR1 and the second region AR2.

The first electronic module EM1 may be disposed under the display panel DP to correspond to the first region AR1. The first electronic module EM1 may receive an external light. For example, the first electronic module EM1 may include an infrared (IR) camera. The IR camera may capture an infrared image using a charge coupling device which is sensitive to an infrared ray (e.g., light having a wavelength ranging from 0.7 μm to 100 μm). The first electronic module EM1 may receive a light reflected from a face FC of a user.

The second electronic module EM2 may be disposed under the display panel DP to correspond to the second region AR2. The second electronic module EM2 may radiate a light IR toward the display panel DP. For example, the second electronic module EM2 may include a dot projector. The dot projector may uniformly radiate the light IR in a specific pattern. In this case, the dot projector may include a light emitting unit to emit the light IR and a diffraction unit to disperse the light IR in the specific pattern.

According to one or more embodiments of the present disclosure, a plurality of second electronic modules EM2 may be provided. The second electronic module EM2 may further include an IR illuminator. The IR illuminator may emit an infrared ray. In this case, the IR illuminator may include a light emitting unit to emit the infrared ray, which is similar to the dot projector.

As the first region AR1 and the second region AR2 have a light transmittance higher than a light transmittance of the first display region DA1, the first electronic module EM1 and the second electronic module EM2 may easily transmit or receive a signal. In addition, as the plurality of pixels PX are disposed in the first region AR1 and the second region AR2, the image IM (see FIG. 2) may be easily displayed.

According to the present disclosure, the second electronic module EM2 may consecutively transmit 30,000 infrared points, which are invisible, to the face FC of the user and capture the infrared points through the first electronic module EM1, thereby performing the mapping for the face pattern of the user. The present disclosure employs a scheme for scanning infrared dots transmitted, instead of merely employing a camera capturing scheme. Accordingly, the user may be recognized even in a dark place having no light. In addition, a curved surface of the face FC is scanned instead of a planar surface, thereby preventing neutralized by a photography. Accordingly, the electronic device 1000 (see FIG. 3) may be provided with improved display quality.

Referring to FIGS. 5, 8A, 10A, 11, and 12, when the second electronic module EM2 is driven, the second region AR2 may have a third temperature due to the light IR and the heat emitted from the second electronic module EM2.

The first region AR1 may have the second temperature due to the heat emitted from the first electronic module EM1.

The first display region DA1 has no heat emitted from the electronic modules EM1 and EM2. The first region AR1 may have heat emitted from the first electronic module EM1, and the second region AR2 may have heat emitted from the light IR, as well as heat emitted from the second electronic module EM2.

The first display region DA1, the first region AR1, and the second region AR2 may have mutually different temperatures. For example, the third temperature may be higher than the second temperature, and the second temperature may be higher than the first temperature of the first display region DA1.

When the temperature is increased, the efficiency of the light emitting element of the plurality of pixels PX may be reduced.

Unlike the present disclosure, when a compensating operation same as a compensating operation for the second pixel PX2 disposed in the first region AR1 is performed with respect to the third pixel PX3, the difference in luminance between the first region AR1 and the second region AR2 may be made. However, according to the present disclosure, mutually different compensating operations may be performed with respect to the plurality of pixels PX disposed in the first display region DA1, the first region AR1, and the second region AR2. The optimal initializing voltage for each temperature may be provided to each of the first display region DA1, the first region AR1, and the second region AR2. The (2-1)-th initializing voltage VAINT1 may have a voltage level higher than a voltage level of the (2-2)-th initializing voltage VAINT2, and the (2-2)-th initializing voltage VAINT2 may have a voltage level higher than a voltage level of the (2-3)-th initializing voltage VAINT3. Accordingly, the electronic device 1000 (see FIG. 2) may be provided with improved display quality and the optimal display front-of-screen performance.

The (2-1)-th initializing voltage VAINT1 may be provided to the first pixel PX1 disposed in the first display region DA1. The anode electrode of the light emitting element ED1 may be compensated by the (2-1)-th initializing voltage VAINT1.

The (2-2)-th initializing voltage VAINT2 may be provided to the second pixel PX2 disposed in the first region AR1. The anode electrode of the light emitting element ED2 may be compensated by the (2-2)-th initializing voltage VAINT2.

The (2-3)-th initializing voltage VAINT3 may be provided to the third pixel PX3 disposed in the second region AR2. The anode electrode of the light emitting element ED3 may be compensated by the (2-3)-th initializing voltage VAINT3.

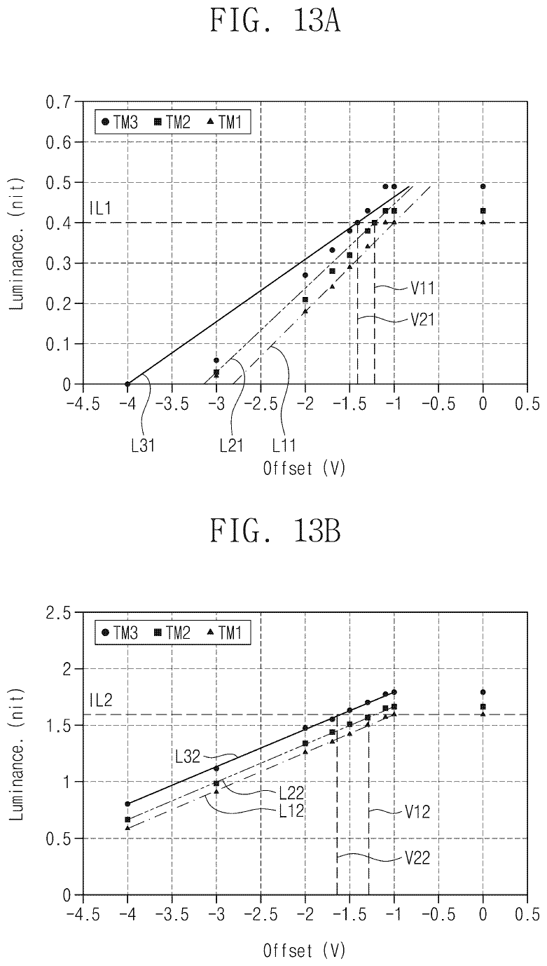

FIG. 13A illustrates graphs of a luminance as a function of a voltage difference according to one or more embodiments of the present disclosure.

Referring to FIGS. 5, 8A, 10A, 11, and 13A, graphs illustrated with respect to luminance as a function of the voltage difference for temperatures at a first gray level. Graphs L11, L21, and L31 may include the first graph L11, the second graph L21, and the third graph L31.

An x axis represents a voltage difference offset from the (2-1)-th initializing voltage VAINT1. The unit of the x axis may be ‘V’ (volt).

A y axis may represent the luminance of the display panel DP. The unit of the y axis may be ‘nit’.

When an input gray level of a white image provided to the display panel DP is the maximum gray level, the input gray level may be referred to as ‘W255’. When the input gray level is the minimum gray level, the input gray level may be referred to as ‘W0’. In addition, ‘Wn’ may be referred to as an n-th input gray level. The first gray level may be defined as ‘W6’ which is a sixth input gray level.

A first luminance IL1 represents the luminance of the first pixel PX1 in the first display region DA1 at the first gray level. For example, the first luminance IL1 may be 0.4 nit.

A first temperature TM1 represents a temperature of the first display region DA1 at the first gray level, when the second electronic module EM2 is driven.

A second temperature TM2 represents a temperature of the first region AR1 at the first gray level, when the second electronic module EM2 is driven. When the first electronic module EM1 is driven, the first region AR1 may have the second temperature TM2 due to the heat emitted from the first electronic module EM1.

A third temperature TM3 represents a temperature of the second region AR2 at the first gray level, when the second electronic module EM2 is driven. When the second electronic module EM2 is driven, the second region AR2 may have the third temperature TM3 due to the light IR and the heat emitted from the second electronic module EM2.

The third temperature TM3 may be higher than the second temperature TM2, and the second temperature TM2 may be higher than the first temperature TM1. For example, the first temperature TM1 may be 26.9° C., the second temperature TM2 may be 31.0° C., and the third temperature TM3 may be 40.0° C.

TABLE 1

| Gray | | Luminance at | Luminance at | Luminance at |
|---|---|---|---|---|
| level | Offset(V) | T1 | T2 | T3 |
| W6 | 0 | 0.4 | 0.43 | 0.49 |
| | −1 | 0.4 | 0.43 | 0.49 |
| | −1.1 | 0.4 | 0.43 | 0.49 |
| | −1.3 | 0.34 | 0.38 | 0.43 |
| | −1.5 | 0.29 | 0.32 | 0.38 |
| | −1.7 | 0.24 | 0.28 | 0.33 |
| | −2 | 0.18 | 0.21 | 0.27 |
| | −3 | 0.02 | 0.03 | 0.06 |
| | −4 | 0.01 | 0.01 | 0.01 |

Table 1 shows the luminance as a function of the voltage difference for each of the first to third temperatures at W6. Each of the first to third graphs L11, L21, and L31 shows a trendline, based on Table 1. Referring to the first to third graphs L11, L21, and L31, when a voltage having a voltage level lower than the voltage level of the (2-1)-th initializing voltage VAINT1 is provided to the seventh transistor T7, the luminance of the plurality of pixels PX may be reduced.

The first graph L11 shows the luminance of the plurality of pixels APX as a function of a voltage difference from the (2-1)-th initializing voltage VAINT1 at the first temperature TM1. For example, the first graph L11 may be defined as a trendline of values (e.g., a triangular dot) obtained by measuring the luminance of the plurality of pixels PX as a function of the voltage difference from the (2-1)-th initializing voltage VAINT1.

The power module 150 (see FIG. 1) may provide the (2-1)-th initializing voltage VAINT1 to the first pixel PX1 disposed in the first display region DA1. For example, the (2-1)-th initializing voltage VAINT1 may be −2.1 V. The (2-1)-th initializing voltage VAINT1 may have a voltage level equal to a voltage level of the second power ELVSS.

The light emitting element ED1 of the first pixel PX1 may be initialized by the (2-1)-th initializing voltage VAINT1. The pixel PX1 may emit a light with a first luminance IL1 at the first gray level. For example, the first luminance IL1 may be 0.4 nit.

The second graph L21 shows the luminance of the plurality of pixels PX as a function of a voltage difference from the (2-1)-th initializing voltage VAINT1 at the second temperature TM2. For example, the second graph L21 may be defined as a trendline of values (e.g., a square dot) obtained by measuring the luminance of the plurality of pixels PX as a function of the voltage difference from the (2-1)-th initializing voltage VAINT1.

The power module 150 (see FIG. 1) may provide the (2-2)-th initializing voltage VAINT2 to the second pixel PX2 disposed in the first region AR1, or may provide a voltage, which is obtained by applying a first offset V11 to the (2-1)-th initializing voltage VAINT1, to the second pixel PX2. In other words, the (2-2)-th initializing voltage VAINT2 may have a voltage level obtained by applying the first offset V11 to the (2-1)-th initializing voltage VAINT1. For example, the (2-2)-th initializing voltage VAINT2 may be −3.26 V, and the first offset V11 may be −1.3 V.

The light emitting element ED2 of the second pixel PX2 may be initialized by the (2-2)-th initializing voltage VAINT2. The second pixel PX2 may emit a light with a first luminance IL1 at the first gray level.

The third graph L31 shows the luminance of the plurality of pixels PX as a function of a voltage difference from the (2-1)-th initializing voltage VAINT1 at the third temperature TM3. For example, the third graph L31 may be defined as a trendline of values (e.g., a circle dot) obtained by measuring the luminance of the plurality of pixels PX as a function of the voltage difference from the (2-1)-th initializing voltage VAINT1.

The power module 150 (see FIG. 1) may provide the (2-3)-th initializing voltage VAINT3 to the third pixel PX3 disposed in the second region AR2, or may provide a voltage, which is obtained by applying a second offset V21 to the (2-1)-th initializing voltage VAINT1, to the third pixel PX3. In other words, the (2-3)-th initializing voltage VAINT3 may have a voltage level obtained by applying the second offset V21 to the (2-1)-th initializing voltage VAINT1. For example, the (2-3)-th initializing voltage VAINT3 may be −3.53 V, and the second offset V21 may be −1.5 V.

The light emitting element ED3 of the third pixel PX3 may be initialized by the (2-3)-th initializing voltage VAINT3. The third pixel PX3 may emit a light with the first luminance IL1 at the first gray level.

The first offset V11 and the second offset V21 may be stored in the form of a look-up table in the memory 120, for use.

When the second electronic module EM2 is not driven, the first display region DA1, the first region AR1, and the second region AR2 may have substantially the same temperature. In this case, the first display region DA1, the first region AR1, and the second region AR2 may have the first temperature TM1. The power module 150 (see FIG. 1) may provide the (2-1)-th initializing voltage VAINT1, the (2-2)-th initializing voltage VAINT2, and the (2-3)-th initializing voltage VAINT3 having the same voltage level, to the display panel DP, or may provide the (2-1)-th initializing voltage VAINT1 to the plurality of pixels PX without applying an offset.

When the second electronic module EM2 is driven, the first display region DA1, the first region AR1, and the second region AR2 may have mutually different temperatures. The (2-1)-th initializing voltage VAINT1, the (2-2)-th initializing voltage VAINT2, and the (2-3)-th initializing voltage VAINT3 may be different from each other. The (2-1)-th initializing voltage VAINT1 may have a voltage level higher than a voltage level of the (2-2)-th initializing voltage VAINT2, and the (2-2)-th initializing voltage VAINT2 may have a voltage level higher than a voltage level of the (2-3)-th initializing voltage VAINT3.

According to the present disclosure, the plurality of pixels PX may be restored to have the same luminance, as a different initializing voltage is applied to each of the plurality of pixels PX, based on a temperature increased for each region.

The change in luminance resulting from thermal energy may be controlled by the first electronic module EM1 and the second electronic module EM2. The luminance difference may not be viewed. Accordingly, the electronic device 1000 (see FIG. 2) may be provided with improved display quality.

TABLE 2

| Gray | | Luminance at | Luminance at | Luminance at |
|---|---|---|---|---|
| level | Offset(V) | T1 | T2 | T3 |
| W255 | 0 | 490 | 493 | 496.8 |
| | −1 | 490 | 493 | 496.8 |
| | −2 | 490 | 492.5 | 496.5 |
| | −3 | 489.7 | 492.1 | 496 |
| | −4 | 489.3 | 491.7 | 495.6 |

Table 2 shows the luminance as a function of the voltage difference for each of the first to third temperatures at W255. As a light is emitted with higher luminance at a higher gray level, the luminance difference may not be actually viewed. When the luminance difference is made in the display region of the display panel DP, the luminance difference at the lower gray level may be more viewed by the user. For example, a tenth input gray level and gray levels lower than the tenth input gray level may be defined as lower gray levels.

According to the present disclosure, mutually different compensating operations may be performed with respect to the plurality of pixels PX disposed in the first display region DA1, the first region AR1, and the second region AR2, at the lower gray level. The optimal initializing voltage for each temperature may be provided to each of the first display region DA1, the first region AR1, and the second region AR2. Accordingly, the electronic device 1000 (see FIG. 2) may be provided with the improved display quality.

FIG. 13B illustrates graphs of a luminance as a function of a voltage difference according to one or more embodiments of the present disclosure. In the following description made with reference to FIG. 13B, the components that have been described with reference to FIG. 13A will be assigned with the same reference numerals, and the details thereof will be omitted.

Referring to FIGS. 5, 8A, 10A, 11, and 13B, the graphs are illustrated with respect to a luminance as a function of the voltage difference for each temperature at a second gray level. Graphs L12, L22, and L32 may include the fourth graph L12, the fifth graph L22, and the sixth graph L32.

The second gray level may be defined as ‘W10’ which is the tenth input gray level.

A second luminance IL2 represents the luminance of the first pixel PX1 in the first display region DA1 at the second gray level. For example, the second luminance IL2 may be 1.6 nit.

TABLE 3

| Gray | | Luminance at | Luminance at | Luminance at |
|---|---|---|---|---|
| level | Offset(V) | T1 | T2 | T3 |
| W10 | 0 | 1.6 | 1.67 | 1.8 |
| | −1 | 1.6 | 1.67 | 1.8 |
| | −1.1 | 1.58 | 1.66 | 1.78 |
| | −1.3 | 1.51 | 1.58 | 1.71 |
| | −1.5 | 1.43 | 1.52 | 1.64 |
| | −1.7 | 1.36 | 1.45 | 1.56 |
| | −2 | 1.27 | 1.35 | 1.48 |
| | −3 | 0.92 | 1 | 1.13 |
| | −4 | 0.6 | 0.68 | 0.82 |

Table 3 shows the luminance as a function of the voltage difference for each of the first to third temperatures at W10. Each of the fourth to sixth graphs L12, L22, and L32 illustrates a trendline, based on Table 2. Referring to the fourth to sixth graphs L12, L22, and L32, when a voltage having a voltage level lower than the voltage level of the (2-1)-th initializing voltage VAINT1 is provided to the seventh transistor T7, the luminance of the plurality of pixels PX may be reduced.

The fourth graph L12 shows the luminance of the plurality of pixels PX as a function of a voltage difference from the (2-1)-th initializing voltage VAINT1 at the first temperature TM1. For example, the fourth graph L12 may be defined as a trendline of values (e.g., a triangular dot) obtained by measuring the luminance of the plurality of pixels PX as a function of the voltage difference from the (2-1)-th initializing voltage VAINT1.

The power module 150 (see FIG. 1) may provide the (2-1)-th initializing voltage VAINT1 to the first pixel PX1 disposed in the first display region DA1. For example, the (2-1)-th initializing voltage VAINT1 may be −2.1V. The (2-1)-th initializing voltage VAINT1 may have a voltage level equal to a voltage level of the second power ELVSS.

The light emitting element ED1 of the first pixel PX1 may be initialized by the (2-1)-th initializing voltage VAINT1. The pixel PX1 may emit a light with a second luminance IL2 at the second gray level. For example, the first luminance IL1 may be 1.6 nit.

The fifth graph L22 shows the luminance of the plurality of pixels PX as a function of a voltage difference from the (2-1)-th initializing voltage VAINT1 at the second temperature TM2. For example, the fifth graph L22 may be defined as a trendline of values (e.g., a square dot) obtained by measuring the luminance of the plurality of pixels PX as a function of the voltage difference from the (2-1)-th initializing voltage VAINT1.

The power module 150 (see FIG. 1) may provide the (2-2)-th initializing voltage VAINT2 to the second pixel PX2 disposed in the first region AR1, or may provide a voltage, which is obtained by applying a third offset V12 to the (2-1)-th initializing voltage VAINT1, to the second pixel PX2. In other words, the (2-2)-th initializing voltage VAINT2 may have a voltage level obtained by applying the third offset V12 to the (2-1)-th initializing voltage VAINT1. For example, the (2-2)-th initializing voltage VAINT2 may be −3.35 V, and the third offset V12 may be −1.3 V.

The light emitting element ED2 of the second pixel PX2 may be initialized by the (2-2)-th initializing voltage VAINT2. The second pixel PX2 may emit a light with a second luminance IL2 at the second gray level.

The sixth graph L32 shows the luminance of the plurality of pixels PX as a function of a voltage difference from the (2-1)-th initializing voltage VAINT1 at the third temperature TM3. For example, the sixth graph L32 may be defined as a trendline of values (e.g., a circle dot) obtained by measuring the luminance of the plurality of pixels PX as a function of the voltage difference from the (2-1)-th initializing voltage VAINT1.

The power module 150 (see FIG. 1) may provide the (2-3)-th initializing voltage VAINT3 to the third pixel PX3 disposed in the second region AR2, or may provide a voltage, which is obtained by applying a fourth offset V22 to the (2-1)-th initializing voltage VAINT1, to the third pixel PX3. In other words, the (2-3)-th initializing voltage VAINT3 may have a voltage level obtained by applying the fourth offset V22 to the (2-1)-th initializing voltage VAINT1. For example, the (2-3)-th initializing voltage VAINT3 may be −3.72 V, and the second offset V21 may be −1.7 V.

The light emitting element ED3 of the third pixel PX3 may be initialized by the (2-3)-th initializing voltage VAINT3. The third pixel PX3 may emit a light with a second luminance IL2 at the second gray level.

The third offset V12 and the fourth offset V22 may be stored in the form of a look-up table in the memory 120, for use.

Unlike the present disclosure, when the (2-2)-th initializing voltage VAINT2 has a voltage level equal to or lower than −3.4 V, the plurality of pixels PX disposed in the first region AR1 may emit a light having a luminance lower than a luminance of the plurality of pixels PX disposed in the first display region DA1. Accordingly, the luminance difference may be viewed by the user. In addition, when the (2-2)-th initializing voltage VAINT2 has a voltage level equal to or higher than ‘0’ V, the light emitting element ED2 of the second pixel PX2 may not be initialized. However, according to the present disclosure, the (2-2)-th initializing voltage VAINT2 may have a voltage level greater than −3.4 V and less than ‘0’ V. The optimal initializing voltage for each temperature may be provided to the first region AR1. Accordingly, the electronic device 1000 (see FIG. 2) may be provided with improved display quality.

The first offset V11 and the third offset V12 may have values greater than-1.3 V and less than ‘0’ V.

Unlike the present disclosure, when the (2-3)-th initializing voltage VAINT3 has a voltage level equal to or lower than −3.8 V, the plurality of pixels PX disposed in the second region AR2 may emit a light having a luminance lower than a luminance of the plurality of pixels PX disposed in the first display region DA1. Accordingly, the luminance difference may be viewed by the user. In addition, when the (2-3)-th initializing voltage VAINT3 has a voltage level equal to or higher than ‘0’ V, the light emitting element ED3 of the third pixel PX3 may not be initialized. However, according to the present disclosure, the (2-3)-th initializing voltage VAINT3 may have a voltage level greater than −3.8 V and less than ‘0’ V. The optimal initializing voltage for each temperature may be provided to the second region AR2. Accordingly, the electronic device 1000 (see FIG. 2) may be provided with improved display quality.

The second offset V21 and the fourth offset V22 may have values greater than −1.7 V and less than ‘0’ V.

According to the present disclosure, mutually different compensating operations may be performed with respect to the plurality of pixels PX disposed in the first display region DA1, the first region AR1, and the second region AR2 at a lower gray level. The optimal initializing voltage for each temperature may be provided to each of the first display region DA1, the first region AR1, and the second region AR2. Accordingly, the electronic device 1000 (see FIG. 2) may be provided with improved display quality.

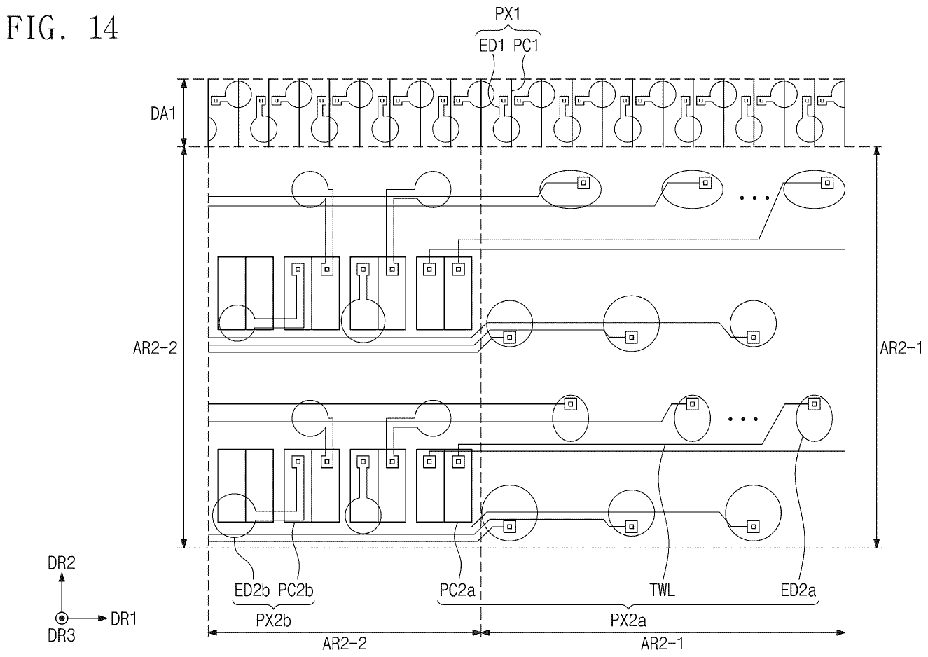

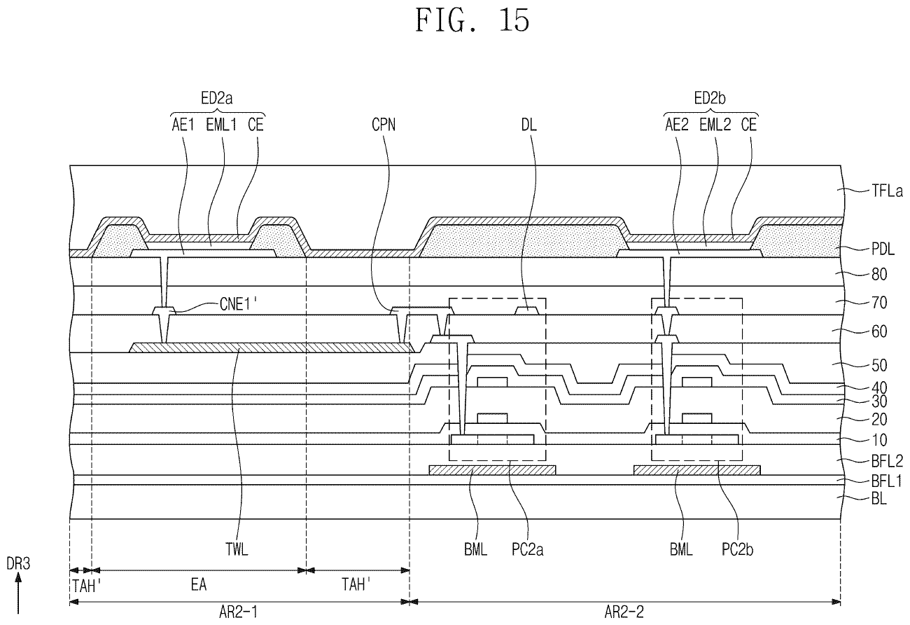

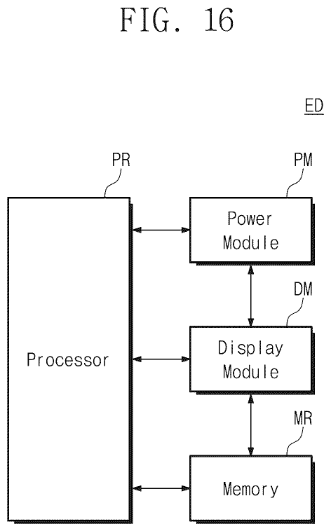

FIG. 14 is a plan view of a display panel according to one or more embodiments of the present disclosure, and FIG. 15 is a cross-sectional view of a display panel according to one or more embodiments of the present disclosure. In the following description made with reference to FIG. 15, the components that have been described with reference to FIG. 6 will be assigned with the same reference numerals, and the details thereof will be omitted.

Referring to FIGS. 7, 14, and 15, the second region AR2 may be defined with a first sub-region AR2-1 and a second sub-region AR2-2 adjacent to the first sub-region AR2-1. The first sub-region AR2-1 may be referred to as a component region, and the second region AR2 may be referred to as an intermediate region or a transition region.

The plurality of pixels PX may include the first pixel PX1 to emit a light in the first display region DA1, a (2-1)-th pixel PX2a to emit a light in the first sub-region AR2-1, and a (2-2)-th pixel PX2b to emit a light in the second sub-region AR2-2.

A plurality of first pixels PX1 may be provided, a plurality of (2-1)-th pixels PX2a may be provided, and a plurality of (2-2)-th pixels PX2b may be provided. In this case, each of the first pixel PX1, the (2-1)-th pixel PX2a, and the (2-2)-th pixel PX2b may include a red pixel, a green pixel, and a blue pixel, respectively, and may further include a white pixel according to one or more embodiments.

The first pixel PX1 may include the light emitting element ED1 and the pixel circuit PC1 to drive the light emitting element ED1, the (2-1)-th pixel PX2a may include a light emitting element ED2a and a pixel circuit PC2a to drive the light emitting element ED2a, and the (2-2)-th pixel PX2b may include a light emitting element ED2b and a pixel circuit PC2b to drive the light emitting element ED2b.

When viewed in a plan view, the (2-1)-th pixel PX2a may be overlapped with the second electronic module EM2 (see FIG. 3). For example, the light IR (see FIG. 12) may be radiated from the second electronic module EM2 (see FIG. 3) through the first sub-region AR2-1.

To ensure the size of the transmissive region, the number of pixels provided in the first sub-region AR2-1 may be smaller than the number of pixels provided in the first display region DA1. A region, which has no light emitting element ED2a, of the first sub-region AR2-1 may be defined as the transmissive region.

The number of the (2-1)-th pixels PX2a disposed in the first sub-region AR2-1 may be smaller than the number of the first pixels PX1 disposed in the first display region DA1, within a unit area or the same area.

The pixel circuit PC2a of the (2-1)-th pixel PX2a may not be disposed in the first sub-region AR2-1. For example, the pixel circuit PC2a may be disposed in the second sub-region AR2-2 or the peripheral region NAA. In this case, the light transmittance of the first sub-region AR2-1 may be increased, when compare to that the pixel circuit PC2a is disposed in the first sub-region AR2-1.

The light emitting element ED2a and the pixel circuit PC2a may be electrically connected to each other through the connection wiring TWL. The connection wiring TWL may be overlapped with the transmissive region of the first sub-region AR2-1. The connection wiring TWL may include a transparent conductive wiring. The transparent conductive wiring may include a transparent conductive material or a light transmissive material. For example, the connection wiring TWL may be formed of a film of transparent conductive oxide (TCO) such as indium tin oxide (ITO), indium zinc oxide (IZO), indium gallium zinc oxide (IGZO), zinc oxide (ZnO), and/or indium oxide (In₂O₃).

The second sub-region AR2-2 may be adjacent to the first sub-region AR2-1. The second sub-region AR2-2 may surround at least a portion of the first sub-region AR2-1. The second sub-region AR2-2 may be a region having a light transmittance lower than the light transmittance of the first sub-region AR2-1.

The second sub-region AR2-2 may include the pixel circuit PC2a of the (2-1)-th pixel PX2a, the light emitting element ED2b of the (2-2)-th pixel PX2b, and the pixel circuit PC2b of the (2-2)-th pixel PX2b. Accordingly, the light transmittance of the second sub-region AR2-2 may be lower than the light transmittance of the first sub-region AR2-1. The resolution of an image displayed on the second sub-region AR2-2 may be lower than the resolution of the image displayed on the first display region DA1.

Layers from the first buffer layer BFL1 to an eighth insulating layer 80 may be disposed on the base layer BL.

The blocking pattern BML may be disposed on the first buffer layer BFL1. The blocking pattern BML may block the electric potential caused by a polarization phenomenon of the base layer BL from exerting an influence on the pixel circuits PC2a and PC2b.

A first connection electrode may be disposed on the sixth insulating layer 60. A seventh insulating layer 70 may be disposed on the sixth insulating layer 60. A second connection electrode electrically connected to the first connection electrode may be disposed on the seventh insulating layer 70. The data line DL may be disposed on the seventh insulating layer 70. The eighth insulating layer 80 may be disposed on the sixth insulating layer 60.

A layer having the light emitting elements ED2a and ED2b disposed therein may be disposed on the eighth insulating layer 80.

The light emitting element ED2a of the (2-1)-th pixel PX2a may include the first electrode AE1, the light emitting layer EML1, and the second electrode CE. The light emitting element ED2b of the (2-2)-th pixel PX2b may include the first electrode AE2, the light emitting layer EML2, and the second electrode CE. The second electrode CE may be commonly provided to the pixels PX. The first electrodes AE1 and AE2 may be disposed on the eighth insulating layer 80.

The pixel defining film PDL may be disposed on the eighth insulating layer 80. The pixel defining film PDL disposed in the first sub-region AR2-1 may have a ring shape, when viewed in a plan view.

In the first sub-region AR2-1, the overlap region between the first electrode AE1 and a part for the pixel defining film PDL may be defined as an element region EA (e.g., the element region EA may also include the light emitting element ED2a and the pixel defining film PDL), and a remaining region may be defined as the transmissive region TAH′.

The first electrode AE1 may be electrically connected to the pixel circuit PC2a disposed in the second sub-region AR2-2. For example, the first electrode AE1 may be electrically connected to the pixel circuit PC2a through the connection wiring TWL and a connection bridge CPN. In this case, the connection wiring TWL may be overlapped with the transparent region TAH′. Accordingly, the connection wiring TWL may include a light transmissive material. The first electrode AE1 may be electrically connected to the connection wiring TWL through the connection electrode CNE1′.

The connection wiring TWL may be interposed between the fifth insulating layer 50 and the sixth insulating layer 60, but the present disclosure is not limited thereto. The connection bridge CPN may be interposed between the sixth insulating layer 60 and the seventh insulating layer 70. The connection bridge CPN may be connected to the connection wiring TWL and the pixel circuit PC2a. An upper insulating layer TFLa may be disposed on the second electrode CE.

FIG. 16 is a block diagram of an electronic device according to one or more embodiments of the present disclosure.

An electronic device according to the present disclosure may be provided in various forms. The electronic device according to the present disclosure may further include a module or a device having various additional functions.

Referring to FIG. 16, an electronic device ED according to one or more embodiments may include a display module DM, a processor PR, a memory MR, and a power module PM.

The processor PR may include at least one of a central processing unit (CPU), an application processor (AP), a graphic processing unit (GPU), a communication processor (CP), an image signal processor (ISP), or a controller. The processor PR may control the power module PM, the display module DM, and the memory MR.

The memory MR may store data information necessary for the operation of the processor PR or the display module DM. When the processor PR runs the application stored in the memory MR, an image data signal and/or an input control signal may be transmitted to the display module DM, and the display module DM may process the transmitted signal and output the image information through the display screen.

The power module PM may include a power converting module to convert power which is supplied from a power supply module such as a power adaptor or a battery device, into power necessary for the operation of the electronic device ED.

The display module DM may operate in response to an electrical signal. Some of individual modules functionally included in one module may be included in the display module DM, and other modules of the individual modules may be provided in the electronic device ED, separately from the display module DM.

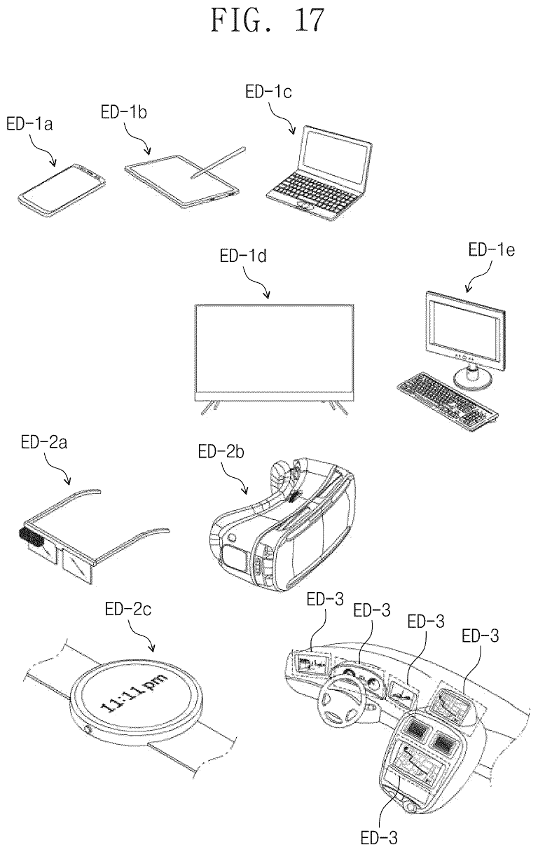

FIG. 17 is a schematic view illustrating an electronic device according to various embodiments.

Referring to FIG. 17, the electronic device according to various embodiments may be a wearable electronic device such as smart glasses ED_2a, a head mounted display ED_2b, and a smart watch ED_2c, as well as an electronic device for image display, such as a smartphone ED_1a, a tablet PC ED_1b, a laptop computer ED_1c, a television ED_1d and a desk monitor ED_1e.

In addition, the electronic device according to various embodiments is applied to an interior of a transport device such as a vehicle to provide, for a user, various pieces of information through an image. For example, a storage device according to the present disclosure may be provided in the form of an electronic device ED-3 for the vehicle including the display module such as a center information display (CID), which is disposed in an instrument panel, a center fascia and a dashboard of a vehicle, or a room mirror display.

As described above, mutually different compensating operations may be performed with respect to the plurality of pixels disposed in each of the second display region, the first region, and the second region. The optimal initializing voltage for each temperature may be provided to the second display region, the first region, and the second region. The initializing voltage provided to the plurality of pixels disposed in the second display region may have the voltage level higher than the voltage level of the initializing voltage provided to the plurality of pixels disposed in the first region. The initializing voltage provided to the plurality of pixels disposed in the first region may have the voltage level higher than the voltage level of the initializing voltage provided to the plurality of pixels disposed in the second region. Accordingly, the electronic device may be provided with the improved image quality. In addition, the electronic device may be provided with the optimal display front-of-screen performance.

Although embodiments of the present disclosure has been described for illustrative purposes, those skilled in the art will appreciate that various modifications, and substitutions are possible, without departing from the scope and spirit of the present disclosure as disclosed in the accompanying claims and their equivalents. Accordingly, the technical scope of the present disclosure is not limited to the detailed description of this specification, but should be defined by the claims and their equivalents.

While the present disclosure has been described with reference to embodiments thereof, it will be apparent to those of ordinary skill in the art that various changes and modifications may be made thereto without departing from the spirit and scope of the present disclosure as set forth in the following claims and their equivalents.

What is claimed is:

1. An electronic device comprising:
a display panel including a first display region having a first light transmittance, and a second display region having a second light transmittance lower than the first light transmittance, wherein the first display region includes a first region and a second region;
a first electronic module under the display panel to correspond to the first region; and
a second electronic module under the display panel to correspond to the second region,
wherein the display panel comprises a plurality of light emitting elements and a plurality of pixel circuits, each of the plurality of pixel circuits being electrically connected to a corresponding one of the plurality of light emitting elements,
wherein a pixel circuit of the plurality of pixel circuits in the first region is configured to provide a first initializing voltage to the corresponding one of the plurality of light emitting elements, and a pixel circuit of the plurality of pixel circuits in the second region is configured to provide a second initializing voltage to the corresponding one of the plurality of light emitting elements, and
wherein the first initializing voltage is different from the second initializing voltage, when the second electronic module is driven.

2. The electronic device of claim 1, wherein the first initializing voltage has a voltage level higher than a voltage level of the second initializing voltage, when the second electronic module is driven.

3. The electronic device of claim 1, wherein the first electronic module receives an external light, and
wherein the second electronic module radiates a light toward the display panel.

4. The electronic device of claim 1, wherein the first electronic module includes an infrared camera, and
wherein the second electronic module includes a dot projector.

5. The electronic device of claim 1, wherein the pixel circuit in the second display region is configured to provide a third initializing voltage, which is different from the first initializing voltage and the second initializing voltage, to the corresponding one of the plurality of light emitting elements.

6. The electronic device of claim 5, wherein the third initializing voltage has a voltage level higher than a voltage level of the first initializing voltage, and the voltage level of the first initializing voltage is higher than a voltage level of the second initializing voltage, when the second electronic module is driven.

7. The electronic device of claim 1, wherein the first initializing voltage has a voltage level greater than −3.4 V (volt) and less than 0 V.

8. The electronic device of claim 1, wherein the second initializing voltage has a voltage level greater than −3.8 V (volt) and less than 0 V.

9. The electronic device of claim 1, wherein the first initializing voltage has a voltage level equal to a voltage level of the second initializing voltage, when the second electronic module is not driven.

10. The electronic device of claim 1, wherein one of the plurality of light emitting elements comprises a first electrode and a second electrode, the second electrode being connected to a first power line configured to provide a first power.

11. The electronic device of claim 10, wherein each of the first initializing voltage and the second initializing voltage has a voltage level lower than a voltage level of the first power, when the second electronic module is not driven.

12. The electronic device of claim 10, wherein one of the plurality of pixel circuits comprises:
a first transistor connected between the first electrode and a second power line configured to provide second power having a voltage level higher than a voltage level of the first power;
a second transistor connected to a data line configured to receive a scan signal; and
a third transistor connected to the first electrode.

13. The electronic device of claim 12, wherein the third transistor of the pixel circuit located in the first region is connected to a first initializing voltage line configured to provide the first initializing voltage.

14. The electronic device of claim 13, wherein the third transistor of the pixel circuit located in the second region is connected to a second initializing voltage line configured to provide the second initializing voltage.

15. An electronic device comprising:
a display panel including a first region and a second region;
a first electronic module overlapped with the first region, when viewed in a plan view; and
a second electronic module overlapped with the second region, when viewed in the plan view,
wherein the display panel comprises a plurality of light emitting elements and a plurality of pixel circuits, each of the plurality of pixel circuits being electrically connected to a corresponding one of the plurality of light emitting elements,
wherein a pixel circuit of the at least one pixel circuit overlapped with the first electronic module is connected to a first initializing voltage line configured to provide a first initializing voltage, and
wherein a pixel circuit of the plurality of pixel circuits overlapped with the second electronic module is connected to a second initializing voltage line configured to provide a second initializing voltage different from the first initializing voltage.

16. The electronic device of claim 15, wherein the first initializing voltage has a voltage level higher than a voltage level of the second initializing voltage.

17. The electronic device of claim 15, wherein the first electronic module is configured to receive an external light, and
wherein the second electronic module is configured to radiate a light toward the display panel.

18. The electronic device of claim 17, wherein the first electronic module comprises an infrared camera, and
wherein the second electronic module comprises a dot projector.

19. The electronic device of claim 15, wherein the first initializing voltage has a voltage level greater than −3.4 V (volt) and less than 0 V, and
wherein the second initializing voltage has a voltage level greater than −3.8 V and less than 0 V.

20. The electronic device of claim 15, wherein one of the plurality of light emitting elements comprises a first electrode and a second electrode, the second electrode connected to a first power line configured to provide a first power, and
wherein each of the first initializing voltage and the second initializing voltage has a voltage level lower than a voltage level of the first power.
